(19) United States
(12) Patent Application Publication
(10) Pub. No.: US 2025/0359132 A1
(43) Pub. Date: Nov. 20, 2025

(54) SEMICONDUCTOR DEVICE AND METHODS OF FABRICATION THEREOF

(71) Applicant: TAIWAN SEMICONDUCTOR MANUFACTURING COMPANY, LTD., Hsinchu (TW)

(72) Inventors: Ting-Hsiang CHANG, New Taipei (TW); Chung-Ting KO, Kaohsiung (TW); Shu Ling LIAO, Taichung (TW); Sung-En LIN, Hsinchu (TW)

(21) Appl. No.: 19/291,646

(22) Filed: Aug. 6, 2025

Related U.S. Application Data
(63) Continuation of application No. 18/403,792, filed on Jan. 4, 2024.
(60) Provisional application No. 63/536,913, filed on Sep. 6, 2023.

(51) Int. Cl. H10D 30/62; H10D 30/01; H10D 30/43; H10D 30/67; H10D 62/10; H10D 64/01

(52) U.S. Cl. CPC H10D 30/62; H10D 30/024; H10D 30/6219; H10D 64/017; H10D 64/018; H10D 30/014; H10D 30/43; H10D 30/6735; H10D 30/6757; H10D 62/121

(57) ABSTRACT

A semiconductor device structure is provided. The semiconductor device structure includes a source/drain (S/D) feature disposed over a substrate and between two adjacent semiconductor layers, an inner spacer disposed between and in contact with one of the semiconductor layers and the substrate, and a dielectric layer structure disposed between the S/D feature and the substrate, the dielectric layer structure comprising a first dielectric layer in contact with the inner spacer and the substrate, and a second dielectric layer nested within the first dielectric layer, wherein a bottom surface and sidewall surfaces of the second dielectric layer are in contact with the first dielectric layer, and a bottom surface of the S/D feature, the first dielectric layer, the second dielectric layer, and the inner spacer define an air gap therebetween.

### CROSS-REFERENCE TO RELATED APPLICATIONS

This application is a continuation application of U.S. patent application Ser. No. 18/403,792 filed Jan. 4, 2024, which claims priority to U.S. Provisional Application Ser. No. 63/536,913 filed Sep. 6, 2023, which is incorporated by reference in their entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down presents new challenge. For example, it becomes an increasing challenge to reduce parasitic capacitance between source/drain features and gate while maintaining desired K value for the devices. Improved structures and methods for manufacturing the same are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 are perspective views of various stages of manufacturing a semiconductor device structure, in accordance with some embodiments.

FIGS. 9A-10A and 15A-21A are cross-sectional side views of various stages of manufacturing the semiconductor device structure taken along cross-section A-A of FIG. 8, in accordance with some embodiments.

FIG. 9A-1 is a cross-sectional side view of the semiconductor device structure, in accordance with an alternative embodiment.

FIGS. 9B-10B and 15B-21B are cross-sectional side views of various stages of manufacturing the semiconductor device structure taken along cross-section B-B of FIG. 8, in accordance with some embodiments.

FIGS. 9C-10C and 15C-21C are cross-sectional side views of various stages of manufacturing the semiconductor device structure taken along cross-section C-C of FIG. 8, in accordance with some embodiments.

FIGS. 11 to 14 are cross-sectional side views of various stages of manufacturing the semiconductor device structure taken along cross-section A-A of FIG. 8, in accordance with some embodiments.

FIGS. 16-1 to 16-5 illustrate an enlarged view of a portion of the semiconductor device structure of FIG. 15A, in accordance with some embodiments.

FIGS. 16-1a and 16-1b illustrate an enlarged view of a portion of the semiconductor device structure of FIG. 16-1, in accordance with some embodiments.

FIGS. 22A and 22B are a flowchart of a method for fabricating the semiconductor device, according to embodiments of the present disclosure.

FIGS. 23 to 35 are cross-sectional side views of various stages of manufacturing the semiconductor device structure taken along cross-section A-A of FIG. 8, in accordance with some alternative embodiments.

FIGS. 36 to 40 illustrate an enlarged view of a portion of the semiconductor device structure based on FIG. 28, in accordance with some embodiments.

FIGS. 36-1a and 36-1b illustrate an enlarged view of a portion of the semiconductor device structure of FIG. 36, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as planar FETs, three-dimensional fin-line FETs (FinFETs), gate-all-around (GAA) devices (e.g., Horizontal Gate All Around (HGAA) FETs, Vertical Gate All Around (VGAA) FETs), vertical FETs, forksheet FETs, or complementary FETs (CFETs). While the embodiments of this disclosure are discussed with respect to GAA devices, implementations of some aspects of the present disclosure may be used in other processes and/or in other devices. A person having ordinary skill in the art will readily understand other modifications that may be made are contemplated within the scope of this disclosure.

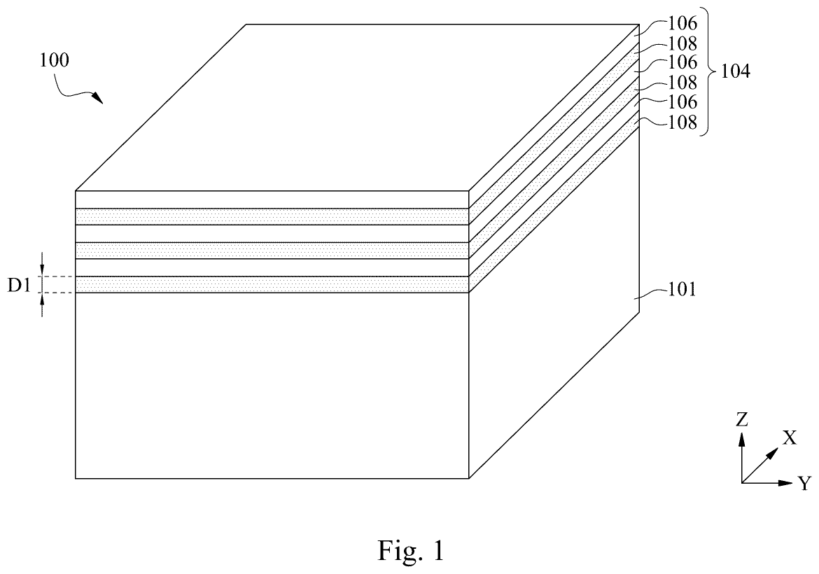

FIGS. 1-40 show exemplary processes for manufacturing a semiconductor device structure 100 according to embodiments of the present disclosure. It is understood that additional operations can be provided before, during, and after processes shown by FIGS. 1-40, and some of the operations described below can be replaced or eliminated, for additional embodiments of the method. The order of the operations/processes is not limiting and may be interchangeable.

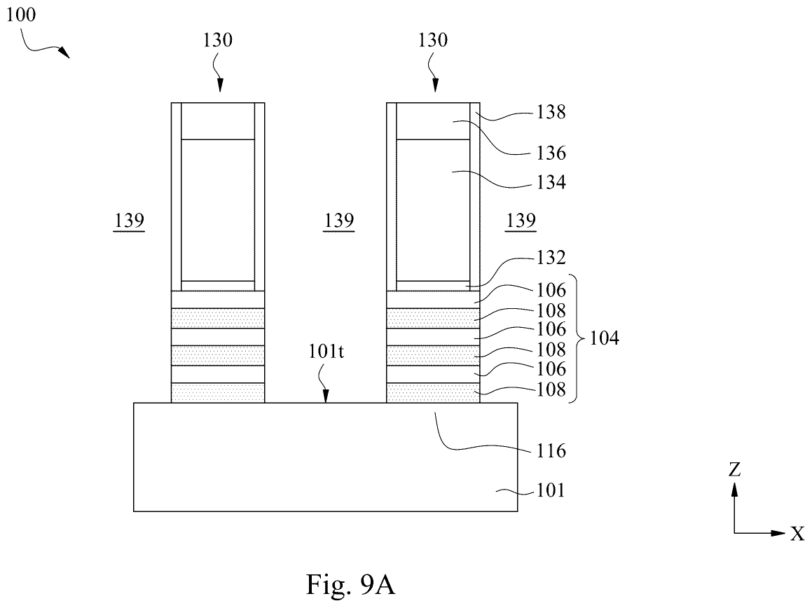

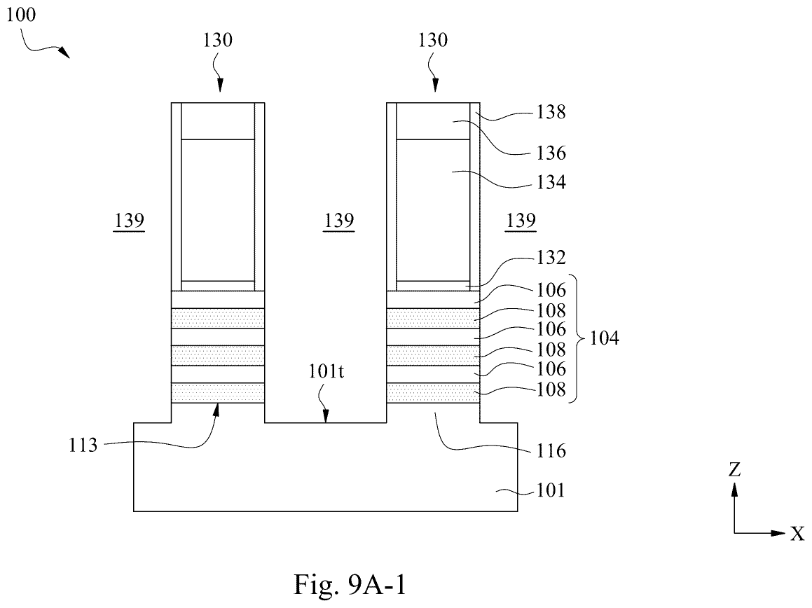

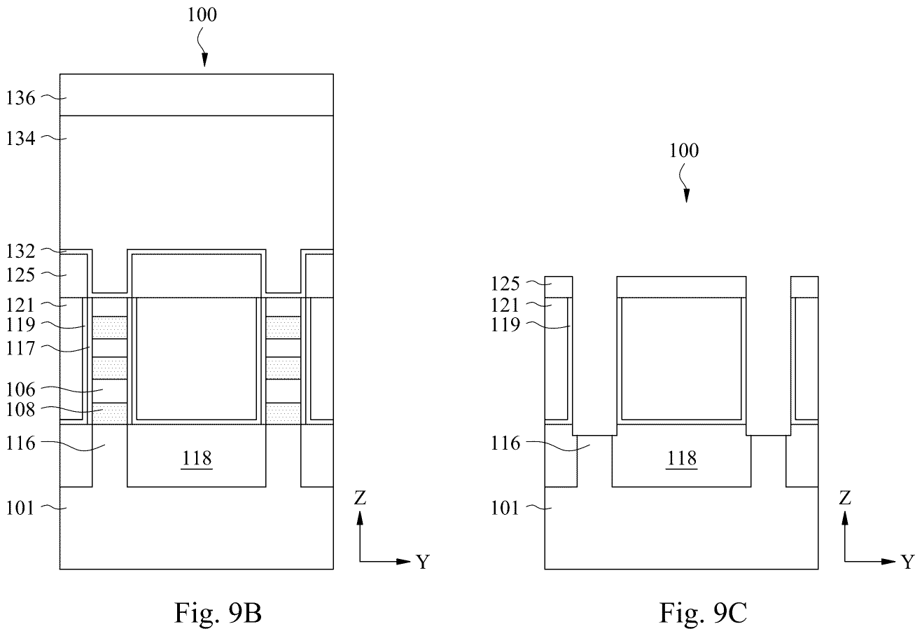

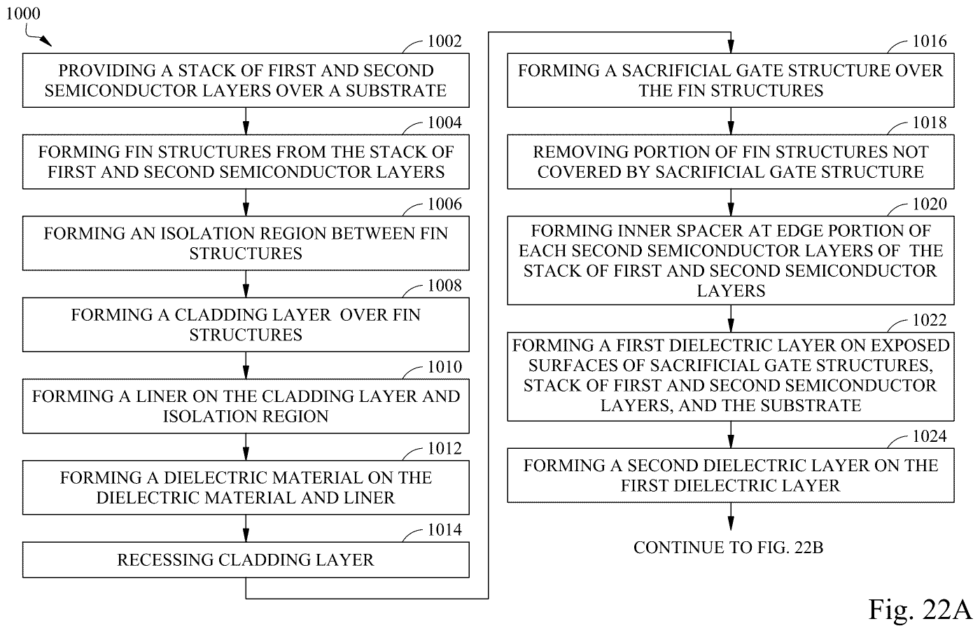

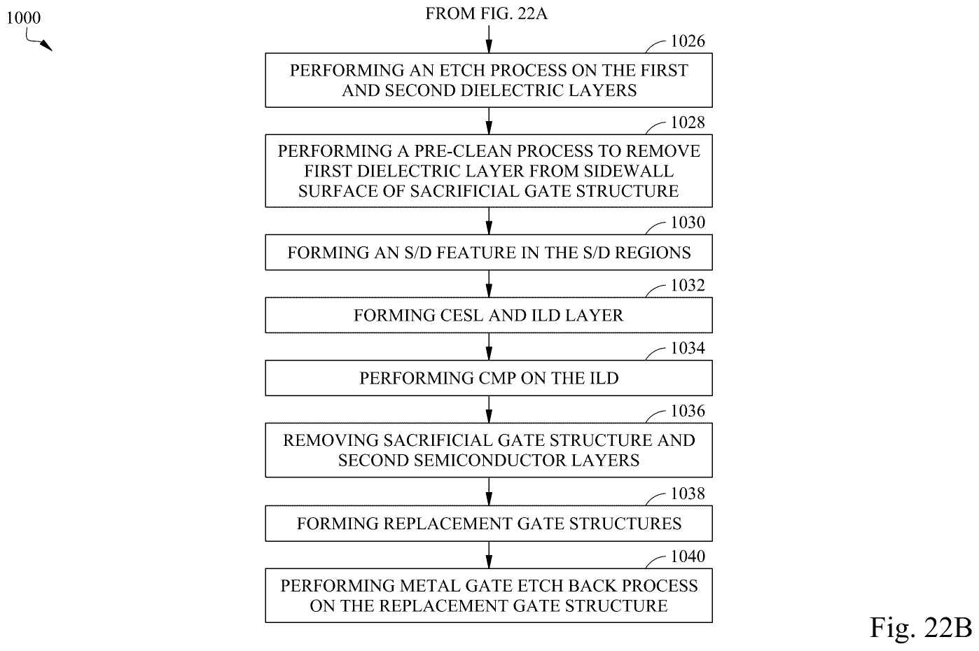

FIGS. 1-8 are perspective views of various stages of manufacturing a semiconductor device structure 100 in accordance with some embodiments. FIGS. 22A and 22B illustrate a flowchart of a method 1000 for fabricating the semiconductor device 100 according to embodiments of the present disclosure. FIGS. 9A-40 schematically illustrate the semiconductor device 100 at various stages of fabrication according to the method 1000. It is understood that additional steps can be provided before, during, and/or after the method 1000, and some of the steps described can be replaced, eliminated, and/or moved around for additional embodiments of the method 1000.

At block 1002, the semiconductor device structure 100 including a stack of semiconductor layers 104 formed over a substrate 101 is provided, as shown in FIG. 1. The substrate 101 may be a semiconductor substrate. The substrate 101 may include a crystalline semiconductor material such as, but not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In one embodiment, the substrate 101 is made of silicon. In some embodiments, the substrate 101 is a silicon-on-insulator (SOI) substrate having an insulating layer (not shown) disposed between two silicon layers for enhancement. In one aspect, the insulating layer is an oxygen-containing layer.

The substrate 101 may include various regions that have been doped with impurities (e.g., dopants having p-type or n-type impurities). Depending on circuit design, the dopants may be, for example boron for p-type field effect transistors (p-type FETs) and phosphorus for n-type field effect transistors (n-type FETs).

The stack of semiconductor layers 104 includes semiconductor layers made of different materials to facilitate formation of nanosheet channels in a multi-gate device, such as nanosheet FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108, and the first and second semiconductor layers 106, 108 are disposed parallelly with each other. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. In some embodiments, the first semiconductor layers 106 may be made of SiGe having a first Ge concentration range, and the second semiconductor layers 108 may be made of SiGe having a second Ge concentration range that is lower or greater than the first Ge concentration range. In any case, the second semiconductor layers 108 may have a Ge concentration in a range between about 20 at. % (atomic percentage) and 30 at. %.

The thickness of the first semiconductor layers 106 and the second semiconductor layers 108 may vary depending on the application and/or device performance considerations. In some embodiments, each first and second semiconductor layer 106, 108 may have a thickness in a range between about 5 nm and about 30 nm. Each second semiconductor layer 108 may have a thickness that is equal to, less than, or greater than the thickness of the first semiconductor layer 106. In some embodiments, each first semiconductor layer 106 has a thickness in a range between about 10 nm and about 30 nm, and each second semiconductor layer 108 has a thickness in a range between about 5 nm to about 20 nm. The second semiconductor layers 108 may eventually be removed and serve to define a vertical distance between adjacent channels for the semiconductor device structure 100.

The first semiconductor layers 106 or portions thereof may form nanosheet channel(s) of the semiconductor device structure 100 in later fabrication stages. The term nanosheet is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanosheet channel(s) of the semiconductor device structure 100 may be surrounded by a gate electrode. The semiconductor device structure 100 may include a nanosheet transistor. The nanosheet transistors may be referred to as nanosheet transistors, nanowire transistors, gate-all-around (GAA) transistors, multi-bridge channel (MBC) transistors, or any transistors having the gate electrode surrounding the channels.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes. While three first semiconductor layers 106 and three second semiconductor layers 108 are alternately arranged as illustrated in FIG. 1, it can be appreciated that any number of first and second semiconductor layers 106, 108 can be formed in the stack of semiconductor layers 104, depending on the predetermined number of nanosheet channels for each FET. For example, the number of first semiconductor layers 106, which is the number of channels, may be between 2 and 8.

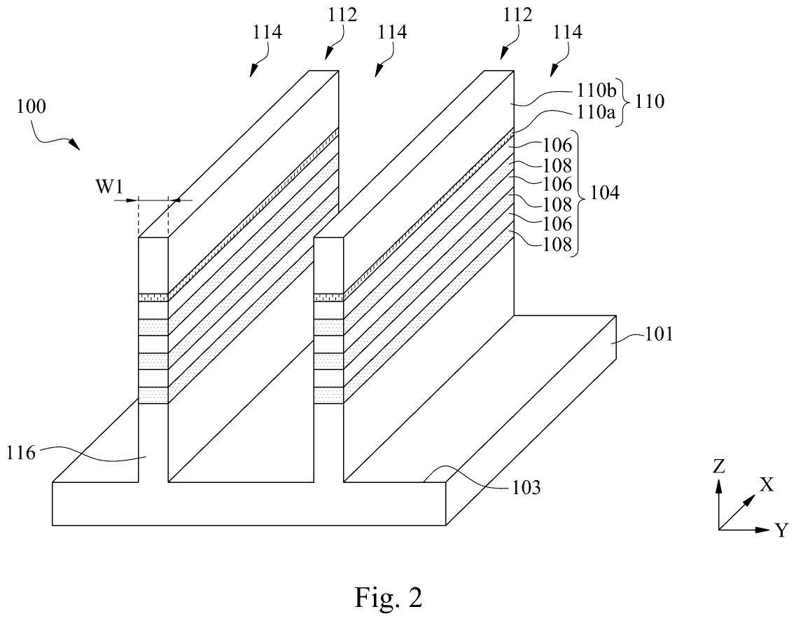

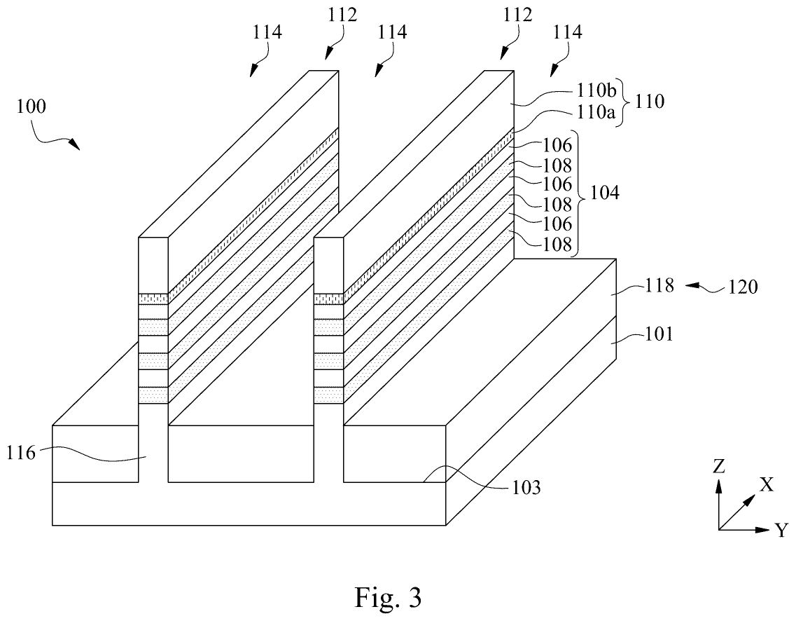

At block 1004, fin structures 112 are formed from the stack of semiconductor layers 104, as shown in FIG. 2. Each fin structure 112 has an upper portion including the semiconductor layers 106, 108 and a well portion 116 formed from the substrate 101. A mask structure 110 is formed over the stack of semiconductor layers 104 prior to forming the fin structures 112. The mask structure 110 may include a pad layer 110a and a hard mask 110b. The pad layer 110a may be an oxygen-containing layer, such as a SiO₂ layer. The hard mask 110b may be a nitrogen-containing layer, such as a Si₃N₄ layer. The mask structure 110 may be formed by any suitable deposition process, such as chemical vapor deposition (CVD) process.

The fin structures 112 may be formed by patterning the mask structure 110 using one or more photolithography processes and etching processes. The etching process can include dry etching, wet etching, reactive ion etching (RIE), and/or other suitable processes. The photolithography process may include double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fin structures 112. In any case, the one or more etching processes form trenches 114 in unprotected regions through the mask structure 110, through the stack of semiconductor layers 104, and into the substrate 101, thereby leaving the plurality of extending fin structures 112. A width W1 of the fin structures 112 along the Y direction may be in a range between about 1.5 nm and about 44 nm, for example about 2 nm to about 6 nm. The trenches 114 may be etched using a dry etch (e.g., RIE), a wet etch, and/or combination thereof. While two fin structures 112 are shown, the number of the fin structures is not limited to two.

FIG. 2 further illustrates the fin structures 112 having substantially vertical sidewalls, such that width of the fin structures 112 are substantially similar and each of the first and second semiconductor layers 106, 108 in the fin structures 112 is rectangular in shape. In some embodiments, the fin structures 112 may have tapered sidewalls, such that a width of each of the fin structures 112 continuously increases in a direction towards the substrate 101. In such cases, each of the first and second semiconductor layers 106, 108 in the fin structures 112 may have a different width and be trapezoidal in shape.

At block 1006, after the fin structures 112 are formed, an insulating material 118 is formed in the trenches 114 between the fin structures 112, as shown in FIG. 3. The insulating material 118 fills the trenches 114 between neighboring fin structures 112 until the fin structures 112 are embedded in the insulating material 118. Then, a planarization operation, such as a chemical mechanical polishing (CMP) process and/or an etch-back process, is performed to expose the top of the fin structures 112. The insulating material 118 may be made of silicon oxide, silicon nitride, silicon oxynitride (SiON), SiOCN, SiCN, fluorine-doped silicate glass (FSG), a low-k dielectric material, or any suitable dielectric material. The insulating material 118 may be formed by any suitable method, such as low-pressure chemical vapor deposition (LPCVD), plasma enhanced CVD (PECVD) or flowable CVD (FCVD).

Thereafter, the insulating material 118 is recessed to form an isolation region 120. After recessing, portions of the fin structures 112, such as the stack of semiconductor layers 104, may protrude from between neighboring isolation regions 120. The isolation regions 120 may have top surfaces that are flat as illustrated, convex, concave, or a combination thereof. The recess of the insulating material 118 reveals the trenches 114 between the neighboring fin structures 112. The insulating material 118 may be recessed using a suitable process, such as a dry etching process, a wet etching process, or a combination thereof. Upon completion of recessing, a top surface of the insulating material 118 may be level with or below a surface of the second semiconductor layers 108 in contact with the well portion 116 formed from the substrate 101.

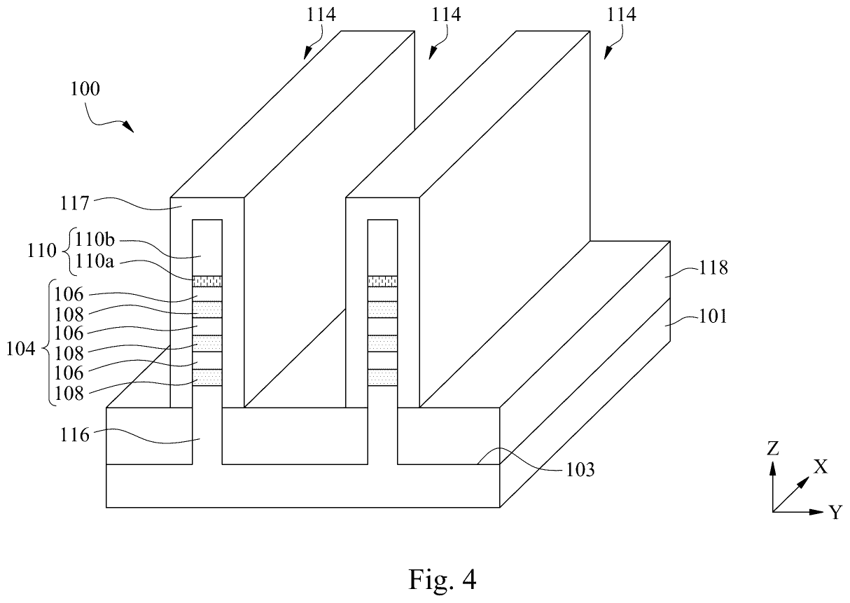

At block 1008, a cladding layer 117 is formed by an epitaxial process over exposed portion of the fin structures 112, as shown in FIG. 4. In some embodiments, a semiconductor liner (not shown) may be first formed over the fin structures 112, and the cladding layer 117 is then formed over the semiconductor liner. The semiconductor liner may be diffused into the cladding layer 117 during the formation of the cladding layer 117. In either case, the cladding layer 117 is in contact with the stack of semiconductor layers 104. In some embodiments, the cladding layer 117 and the second semiconductor layers 108 include the same material having the same etch selectivity. For example, the cladding layer 117 and the second semiconductor layers 108 may be or include SiGe. The cladding layer 117 and the second semiconductor layers 108 may be removed subsequently to create space for the subsequently formed gate electrode layer.

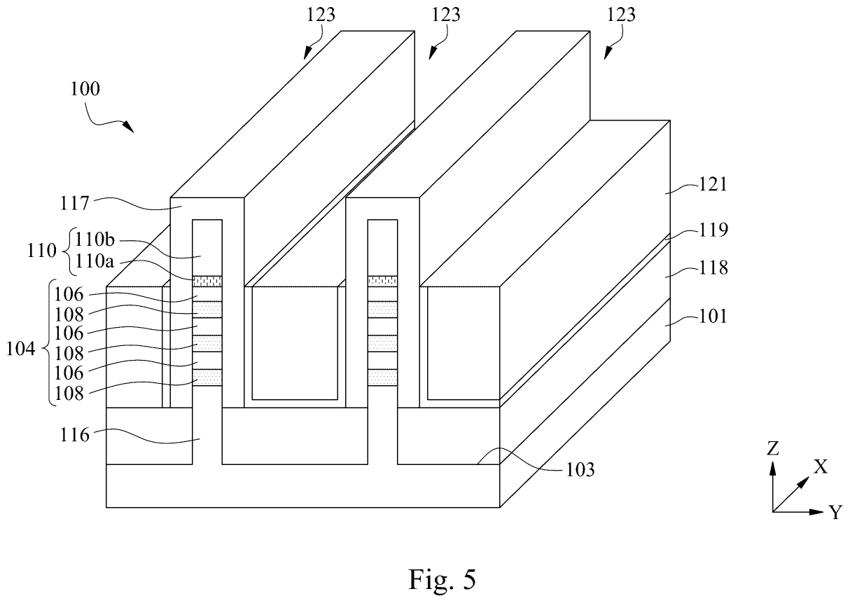

At block 1010, a liner 119 is formed on the cladding layer 117 and the top surface of the insulating material 118, as shown in FIG. 5. The liner 119 may include a material having a k value lower than 7, such as SiO₂, SiN, SiCN, SiOC, or SiOCN. The liner 119 may be formed by a conformal process, such as an ALD process. A dielectric material 121 is then formed in the trenches 114 (FIG. 4) and on the liner 119. The dielectric material 121 may be an oxygen-containing material, such as an oxide, formed by FCVD. The oxygen-containing material may have a k value less than about 7, for example less than about 3. A planarization process, such as a CMP process, may be performed to remove portions of the liner 119 and the dielectric material 121 formed over the fin structures 112. The portion of the cladding layer 117 disposed on the hard mask 110b is exposed after the planarization process.

Next, the liner 119 and the dielectric material 121 are recessed to the level of the topmost first semiconductor layer 106. For example, in some embodiments, after the recess process, the top surfaces of the liner 119 and the dielectric material 121 may be level with a top surface of the uppermost first semiconductor layer 106. The recess processes may be selective etch processes that do not substantially affect the semiconductor material of the cladding layer 117. As a result of the recess process, trenches 123 are formed between the fin structures 112.

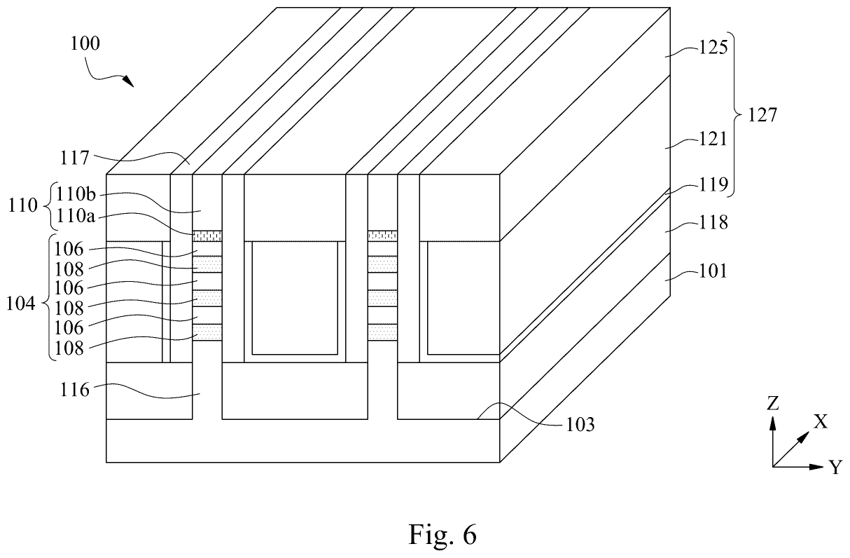

At block 1012, a dielectric material 125 is formed in the trenches 123 (FIG. 5) and on the dielectric material 121 and the liner 119, as shown in FIG. 6. The dielectric material 125 may include SiO, SiN, SiC, SiCN, SiON, SiOCN, AIO, AlN, AlON, ZrO, ZrN, ZrAlO, HfO, or other suitable dielectric material. In some embodiments, the dielectric material 125 includes a high-k dielectric material (e.g., a material having a k value greater than 7). The dielectric material 125 may be formed by any suitable process, such as a CVD, PECVD, FCVD, or ALD process. A planarization process, such as a CMP process, is performed until the hard mask 110b of the mask structure 110 is exposed. The planarization process removes portions of the dielectric material 125 and the cladding layer 117 disposed over the mask structure 110. The liner 119, the dielectric material 121, and the dielectric material 125 together may be referred to as a dielectric feature 127 or a hybrid fin. The dielectric feature 127 serves to separate subsequent formed source/drain (S/D) epitaxial features and adjacent gate electrode layers.

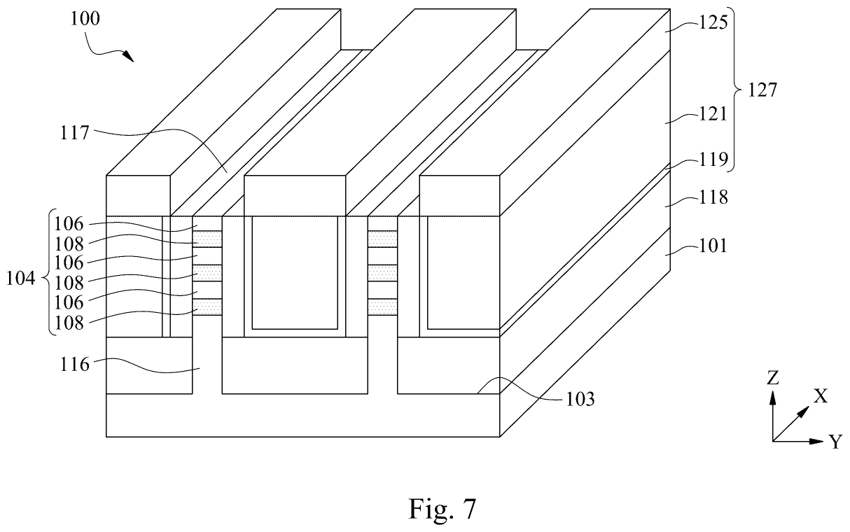

At block 1014, the cladding layers 117 are recessed, and the mask structures 110 are removed, as shown in FIG. 7. The recess of the cladding layers 117 may be performed by any suitable process, such as dry etch, wet etch, or a combination thereof. The recess process may be controlled so that the remaining cladding layers 117 are substantially at the same level as the top surface of the uppermost first semiconductor layer 106 in the stack of semiconductor layers 104. The etch process may be a selective etch process that does not substantially affect the dielectric material 125. The removal of the mask structures 110 may be performed by any suitable process, such as dry etch, wet etch, or a combination thereof.

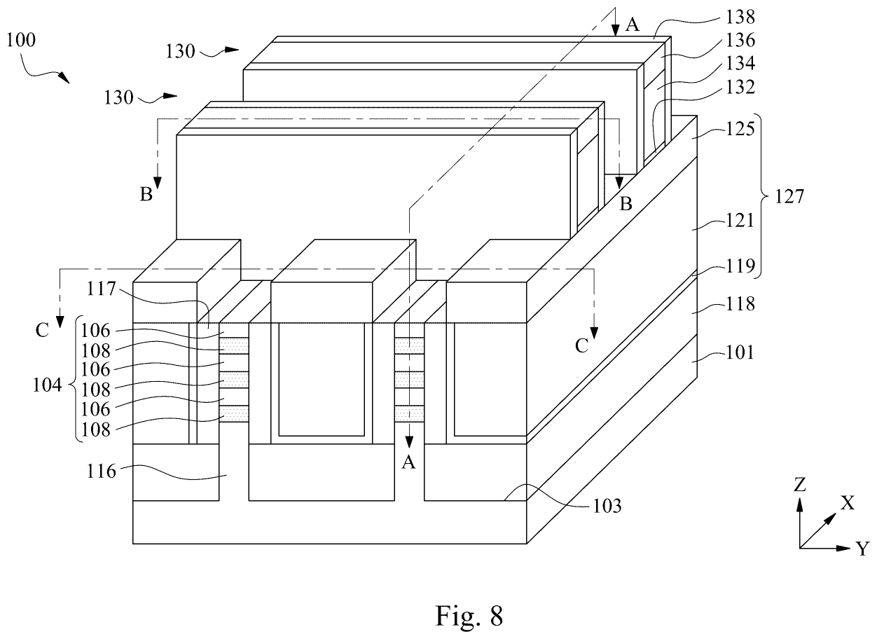

At block 1016, one or more sacrificial gate structures 130 (only two is shown) are formed over the semiconductor device structure 100, as shown in FIG. 8. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, followed by pattern and etch processes. For example, the pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof.

By patterning the sacrificial gate structure 130, the stacks of semiconductor layers 104 of the fin structures 112 are partially exposed on opposite sides of the sacrificial gate structure 130. The portions of the fin structures 112 that are covered by the sacrificial gate electrode layer 134 of the sacrificial gate structure 130 serve as channel regions for the semiconductor device structure 100. The fin structures 112 that are partially exposed on opposite sides of the sacrificial gate structure 130 define source/drain (S/D) regions for the semiconductor device structure 100. In some cases, some S/D regions may be shared between various transistors. For example, various one of the S/D regions may be connected together and implemented as multiple functional transistors. While two sacrificial gate structures 130 are shown, more or less sacrificial gate structures 130 may be arranged along the X direction in some embodiments.

Next, gate spacers 138 are formed on sidewalls of the sacrificial gate structures 130. The gate spacers 138 may be formed by first depositing a conformal layer that is subsequently etched back to form sidewall gate spacers 138. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fin structures 112, the cladding layer 117, the dielectric material 125, leaving the gate spacers 138 on the vertical surfaces, such as the sidewalls of sacrificial gate structures 130. The gate spacer 138 may be made of a dielectric material such as silicon oxide, silicon nitride, silicon carbide, silicon oxynitride, SiCN, silicon oxycarbide, SiOCN, and/or combinations thereof.

In some embodiments where the cladding layers 117 and the dielectric features 127 are not present, portions of the sacrificial gate structures 130 and the gate spacers 138 are formed on the insulating material 118, and gaps are formed between exposed portions of the fin structures 112.

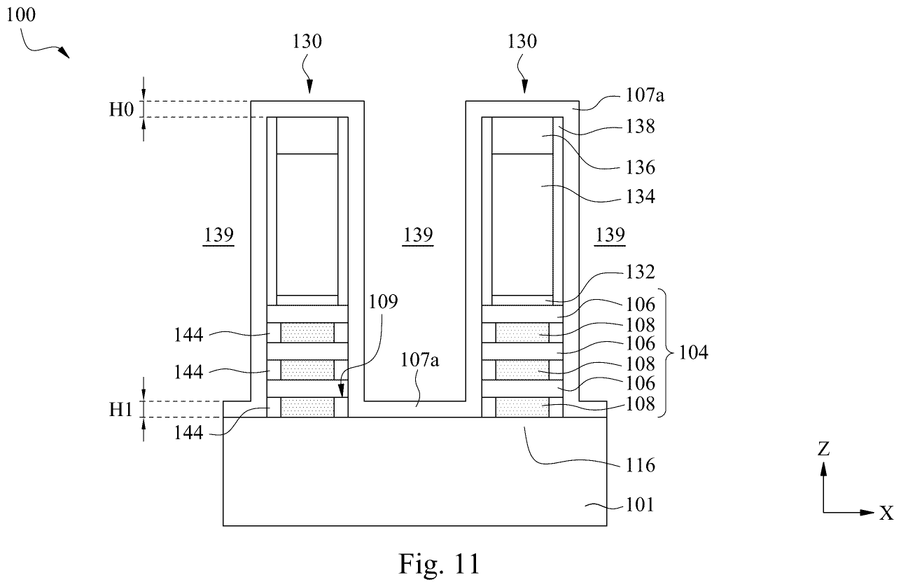

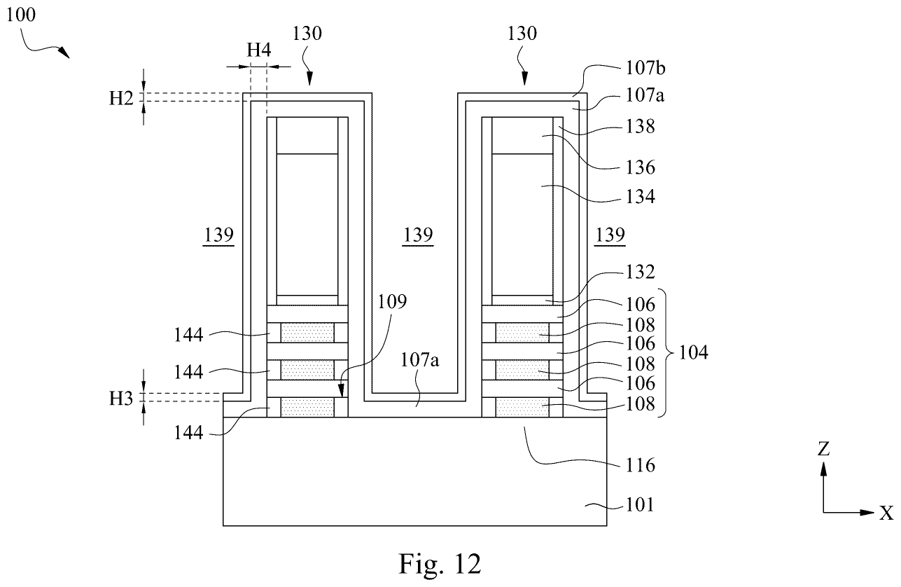

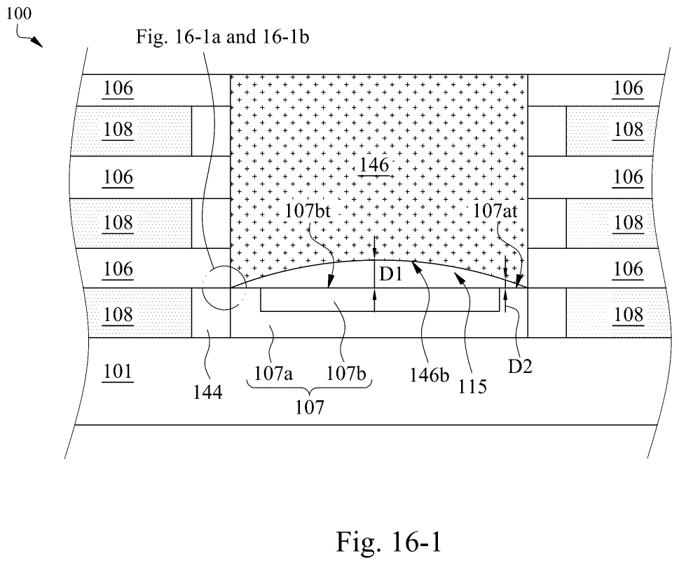

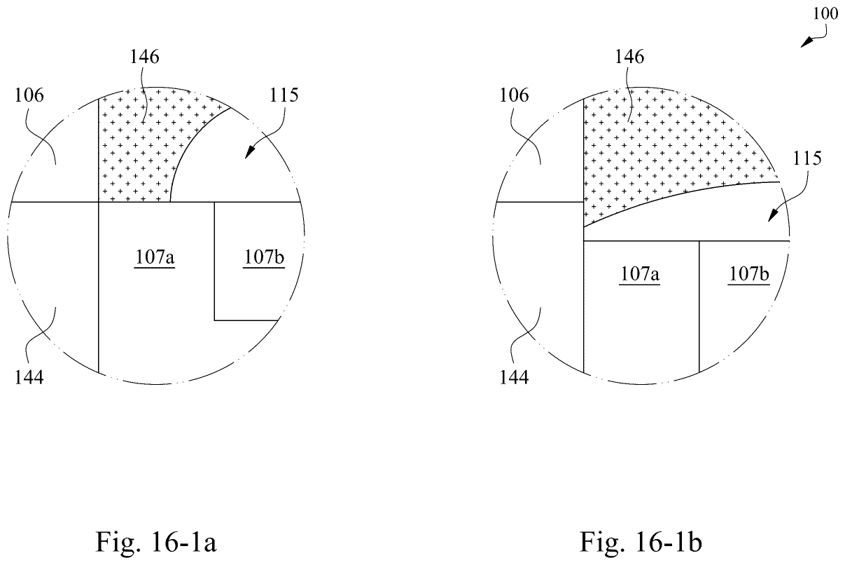

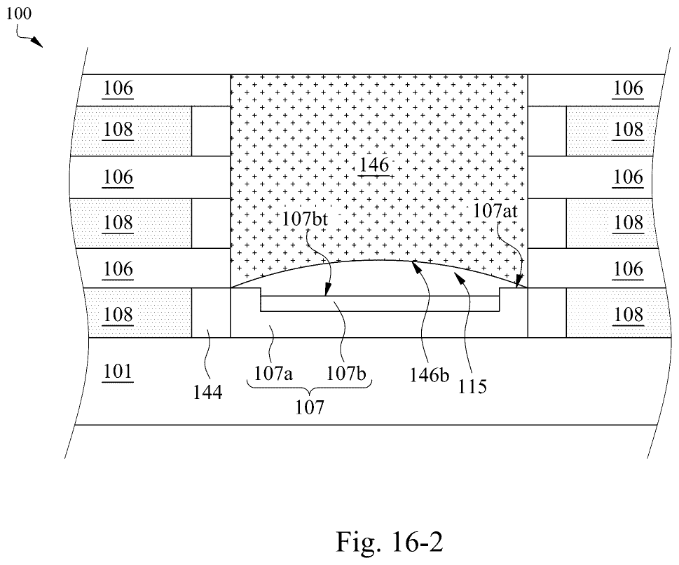

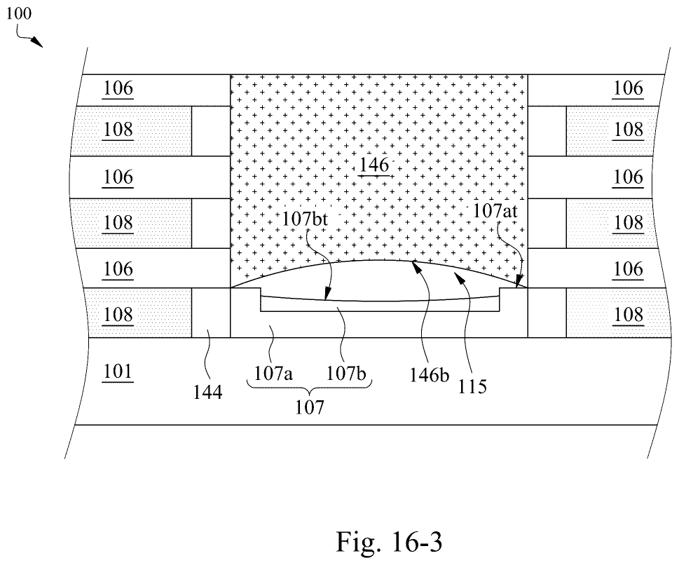

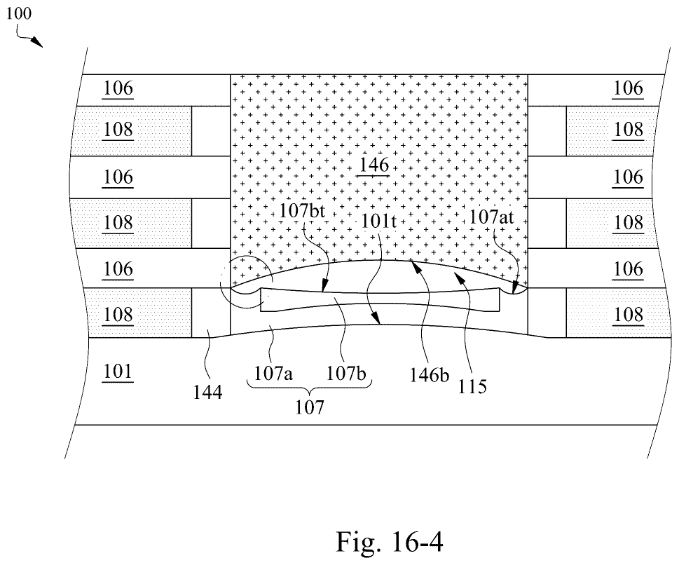

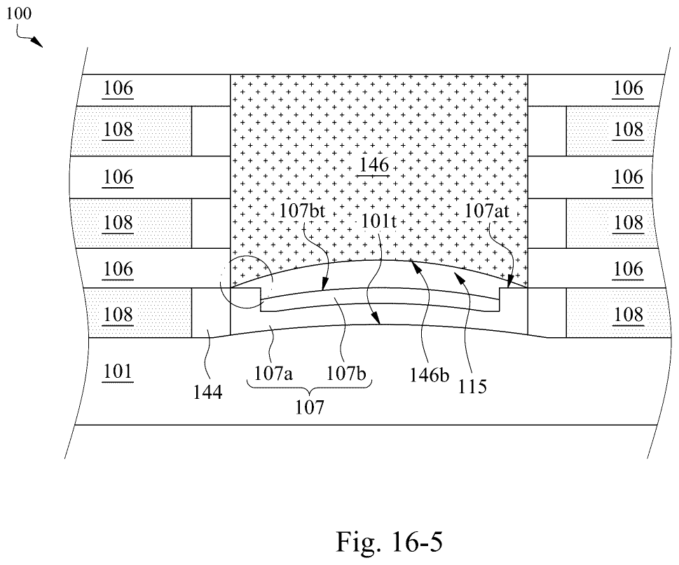

FIGS. 9A-10A and 16A-21A are cross-sectional side views of various stages of manufacturing the semiconductor device structure 100 taken along cross-section A-A of FIG. 8, in accordance with some embodiments. FIGS. 9B-10B and 15B-21B are cross-sectional side views of various stages of manufacturing the semiconductor device structure 100 taken along cross-section B-B of FIG. 8, in accordance with some embodiments. FIGS. 9C-10C and 15C-21C are cross-sectional side views of various stages of manufacturing the semiconductor device structure 100 taken along cross-section C-C of FIG. 8, in accordance with some embodiments. FIGS. 11 to 15A are cross-sectional side views of various stages of manufacturing the semiconductor device structure 100 taken along cross-section A-A of FIG. 8, in accordance with some embodiments. Cross-section A-A is in a plane of the fin structure 112 along the X direction. Cross-section B-B is in a plane perpendicular to cross-section A-A and is in the sacrificial gate structure 130. Cross-section C-C is in a plane perpendicular to cross-section A-A and is in the S/D epitaxial features 146 (FIG. 16-1) along the Y-direction.

At block 1018, exposed portions of the stacks of semiconductor layers 104 of the fin structures 112, exposed portions of the cladding layers 117, and a portion of the exposed dielectric material 125 not covered by the sacrificial gate structures 130 and the gate spacers 138 are removed to form recess 139 for the S/D features, as shown in FIGS. 9A and 9C. The removal of the layers may be done by using one or more suitable etch processes, such as dry etch, wet etch, or a combination thereof. The one or more etch processes may be performed until the well portions 116 are exposed. The exposed portions of the fin structures 112 may be recessed so that a top surface 101t of the exposed portions of the fin structures 112 is at a level at the bottom surface of the second semiconductor layer 108 in contact with the well portion 116 of the substrate 101.

In some embodiments, the one or more etch processes are performed so that the top surface 101t of the exposed portions of the fin structures 112 is at a level below an interface 113 defined by the bottom surface of the second semiconductor layer 108 and the well portion 116 of the substrate 101, as shown in FIG. 9A-1.

At block 1020, edge portions of each second semiconductor layer 108 of the stack of semiconductor layers 104 are removed horizontally along the X direction. The removal of the edge portions of the second semiconductor layers 108 forms cavities. In some embodiments, the portions of the second semiconductor layers 108 are removed by a selective wet etching process. In cases where the second semiconductor layers 108 are made of SiGe and the first semiconductor layers 106 are made of silicon and/or SiGe having lower germanium concentration than the second semiconductor layers 108, the second semiconductor layer 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

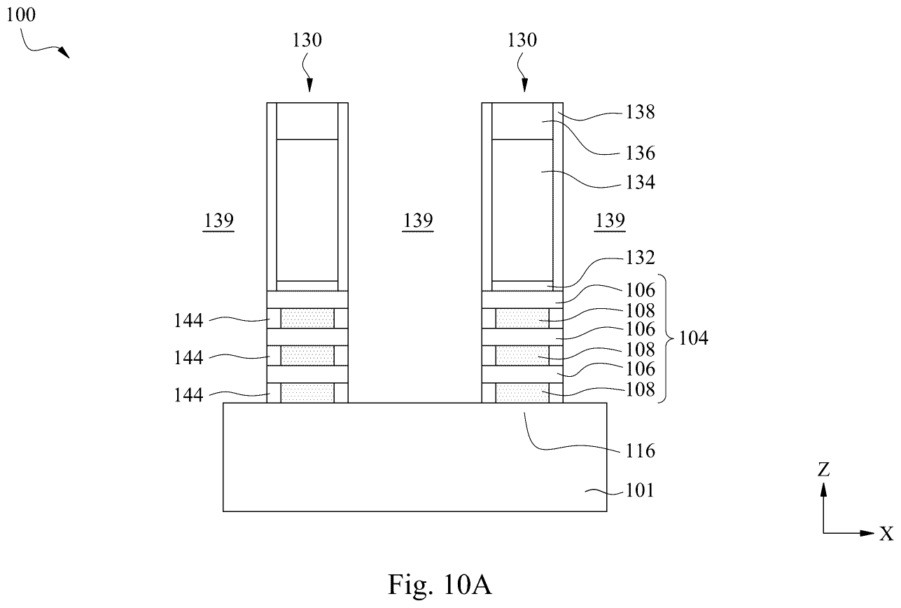

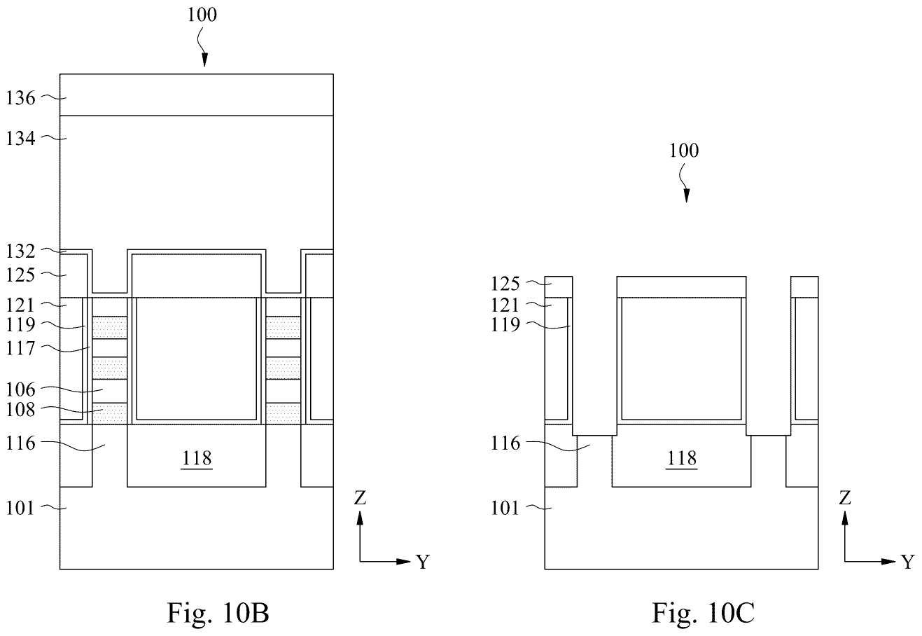

After removing edge portions of each second semiconductor layers 108, a dielectric layer is deposited in the cavities to form dielectric spacers (or so-called inner spacer) 144, as shown in FIG. 10A. The inner spacers 144 may be made of SiON, SiCN, SiOC, SiOCN, or SiN. The inner spacers 144 may be formed by first forming a conformal dielectric layer using a conformal deposition process, such as ALD, followed by an anisotropic etching to remove portions of the conformal dielectric layer other than the inner spacers 144. The inner spacers 144 are protected by the first semiconductor layers 106 during the anisotropic etching process. The remaining second semiconductor layers 108 are capped between the inner spacers 144 along the X direction.

At block 1022, a first dielectric layer 107a is formed on exposed surfaces of the sacrificial gate structures 130 and the stack of semiconductor layers 104, and the exposed surfaces of the substrate 101, as shown in FIG. 11. The first dielectric layer 107a may be conformally formed on the top surface and sidewall surfaces of the sacrificial gate structures 130. In some embodiments, the first dielectric layer 107a is deposited so that the first dielectric layer 107a on the horizontal surfaces of the semiconductor device structure 100, such as the top surface of the sacrificial gate structures 130 has a rounded head or curved (e.g., convex) profile. The first dielectric layer 107a serves as a sidewall etch stop layer that protects the inner spacers 144 from damaging during downstream etching processes (e.g., removal of the second dielectric layer 107b (FIG. 12)). The first dielectric layer 107a on the top surface of the substrate 101 becomes a blocking layer for epitaxy source/drain leakage reduction and parasitic capacitance reduction between source/drain features and gate. The first dielectric layer 107a on the top surface of the sacrificial gate structures 130 may have a thickness H0, and the first dielectric layer 107a on the top surface of the substrate 101 may have a thickness H1 less than the thickness H0 due to the high aspect ratio of the recess 139 between two neighboring sacrificial gate structures 130.

The first dielectric layer 107a may be deposited such that a highest point (e.g., center point) of the first dielectric layer 107a on the top surface of the substrate 101 is at an elevation higher, equal to, or lower than an interface 109 defined by the bottommost first semiconductor layer 106 and bottommost inner spacer 144. In some cases where the embodiment of FIG. 9A-1 is adapted, the highest point of the first dielectric layer 107a on the top surface of the substrate 101 is at an elevation between a bottom surface of the bottommost inner spacer 144 and the top surface 101t of the substrate 101.

In some embodiments, the first dielectric layer 107a is deposited such that a highest point (e.g., center point) of the first dielectric layer 107a on the top surface of the substrate 101 is at an elevation substantially the same as the interface 109 defined by the bottommost first semiconductor layer 106 and bottommost inner spacer 144.

The first dielectric layer 107a may include or be formed of an oxide-based material. In some embodiments, the first dielectric layer 107a includes silicon. Exemplary material for the first dielectric layer 107a may include, but is not limited to, SiO₂, SiON, SiOC, or the like. The first dielectric layer 107a may be deposited using ALD, CVD, or any suitable conformal deposition technique.

At block 1024, a second dielectric layer 107b is formed on the first dielectric layer 107a, as shown in FIG. 12. The second dielectric layer 107b may be conformally formed on the exposed surfaces of the first dielectric layer 107a. In some embodiments, the second dielectric layer 107b is deposited so that the second dielectric layer 107b follows the profile of the first dielectric layer 107a. The second dielectric layer 107b may work with the first dielectric layer 107a to help reduce epitaxy source/drain leakage and parasitic capacitance between source/drain features and gate. In some embodiments, the second dielectric layer 107b over the top surface of the sacrificial gate structures 130 may have a thickness H2, and the second dielectric layer 107b over the top surface of the substrate 101 may have a thickness H3 less than the thickness H2 due to the high aspect ratio of the recess 139 between two neighboring sacrificial gate structures 130. In some embodiments, the thickness H2 is less than the thickness H0. A thicker first dielectric layer 107a allows the second dielectric layer 107b to be removed without affecting the integrity of the inner spacers 144. In some embodiments, the thickness H2 is substantially identical to the thickness H0. In some embodiments, the thickness H2 is greater than the thickness H0.

In various embodiments, the second dielectric layer 107b may include or be formed of a nitride-based material. In some embodiments, the first and second dielectric layers 107a, 107b are formed of a material chemically different from one other. For example, the first dielectric layer 107a may be formed of a nitride-based material, and the second dielectric layer 107b may be formed of an oxide-based material. In some embodiments, the second dielectric layer 107b includes silicon. Exemplary material for the second dielectric layer 107b may include, but is not limited to, SiN, SiON, SiCN, SiOCN, or the like. The second dielectric layer 107b may be deposited using ALD, CVD, or any suitable conformal deposition technique.

The second dielectric layer 107b may be deposited by a plasma-based deposition process. The deposition process may be anisotropic. Due to the high aspect ratio of the recess 139 between neighboring sacrificial gate structures 130, the anisotropic plasma may cause the second dielectric layer 107b to deposit with different film density, growth rate, and etch rate, etc. For example, the second dielectric layer 107b over the top surfaces of the sacrificial gate structures 130 and the substrate 101 may have a first film property, and the second dielectric layer 107b over the sidewall surfaces of the sacrificial gate structures 130 and the stack of semiconductor layers 104 may have a second film property that is different than the first film property.

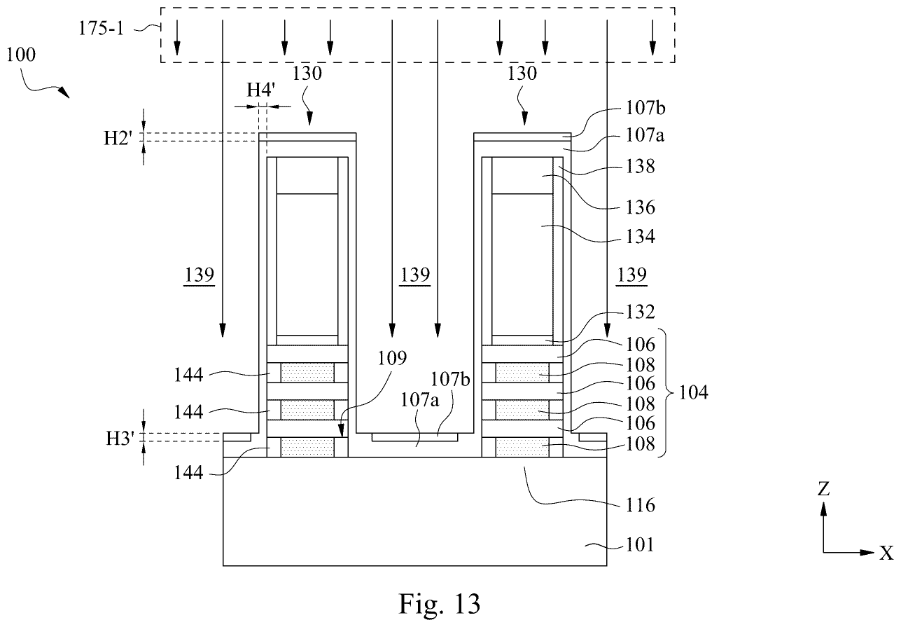

At block 1026, the semiconductor device structure 100 is subjected to an etch process 175-1 to remove a portion of the first dielectric layer 107a and the second dielectric layer 107b, as shown in FIG. 13. The etch process 175-1 may be performed in an isotropic or anisotropic manner such that the second dielectric layer 107b over the top surface and sidewall surface of the sacrificial gate structures 130 and the second dielectric layer 107b over the top surface of the substrate 101 are reduced in thickness. For example, the second dielectric layer 107b over the top surface of the sacrificial gate structures 130 may have a thickness reduced from the thickness H2 (FIG. 12) to H2′, and the thickness of the second dielectric layer 107b over the top surface of the substrate 101 is reduced from H3 (FIG. 12) to H3′. Due to the different film property of the second dielectric layer 107b between the top surface of the sacrificial gate structures 130 and the sidewall surface of the sacrificial gate structures 130, the first and second dielectric layers 107a, 107b are removed at different rates. After the etch process 175-1, the second dielectric layer 107b over the sidewall surfaces of the sacrificial gate structures 130 is fully removed, while the first dielectric layer 107a over the sidewall surfaces of the sacrificial gate structures 130 may have a thickness reduced from the thickness H4 (FIG. 12) to H4′. The etch process 175-1 may be performed so that the first and second dielectric layers 107a, 107b over the top surface of the substrate 101 are etched with different profiles, as will be discussed in more detail in FIGS. 16-1 to 16-5.

The first dielectric layer 107a protects the inner spacers 144 during the removal of the second dielectric layer 107b. If the first dielectric layer 107a were not presented, the inner spacers 144 may be damaged and form a dishing profile while removing the second dielectric layer 107b. The dishing profile of the inner spacers 144 may act as a weak point and allow the etchant used in the subsequent pre-clean process (prior to formation of epitaxial S/D features 146) to further consume the inner spacers 144 and induce air gaps therein. After the epitaxial S/D features 146 are formed, the air gaps are trapped between the epitaxial S/D features 146 and the inner spacers 144, thereby impacting yield and the performance of the device. The use of the first dielectric layer 107a creates an etch rate difference between the inner spacers 144 and the sidewall surface of the first dielectric layer 107a in order to reduce dishing phenomenon on the inner spacers 144. As a result, the integrity of the inner spacers 144 are preserved after the removal of the second dielectric layers 107b and the subsequent pre-clean process.

The etch process 175-1 may be a dry etch, a wet etch, or a combination thereof. In some embodiments, the etch process 175-1 is a wet etch process using NH₄OH, HF or diluted HF, deionized (DI) water, tetramethylammonium hydroxide (TMAH), other suitable solution, or a combination thereof. In some embodiments, the etch process 175-1 may be a standard clean-2 (SC2) followed by a standard clean-1 (SC1), where the SC2 is a mixture of DI water, hydrochloric (HCl) acid, and hydrogen peroxide (H₂O₂), and the SC1 is a mixture of DI water, NH₄OH, and H₂O₂. In some embodiments, an isopropyl alcohol (IPA) may be used after the SC1. Other suitable wet etch process, such as an APM process, which includes at least water (H₂O), ammonium hydroxide (NH₄OH), and hydrogen peroxide (H₂O₂), a HPM process, which includes at least H₂O, H₂O₂, and hydrogen chloride (HCl), a SPM process (also known as piranha clean), which includes at least H₂O₂ and sulfuric acid (H₂SO₄), or any combination thereof, may also be used.

In some embodiments, the etch process 175-1 is a dry etch process using plasma or a radical of species. For example, the etch process 175-1 may use reactive species generated from hydrogen-containing gases in-situ in a reaction chamber or in the upstream of a reaction chamber (e.g., from a remote plasma generator). In some embodiments, the etch process 175-1 is a plasma etching process. Exemplary reactive species may include hydrogen plasma or neutral radical species of hydrogen, such as hydrogen radicals or atomic hydrogen. Other chemistry such as fluorine-containing, chlorine-containing, or oxygen-containing gases, or a combination thereof, may also be used. The plasma etching process may be any suitable plasma-based process, such as a decoupled plasma process, a remote plasma process, or a combination thereof. The plasma may be formed by a capacitively coupled plasma (CCP) source or an inductively coupled plasma (ICP) source driven by an RF power generator.

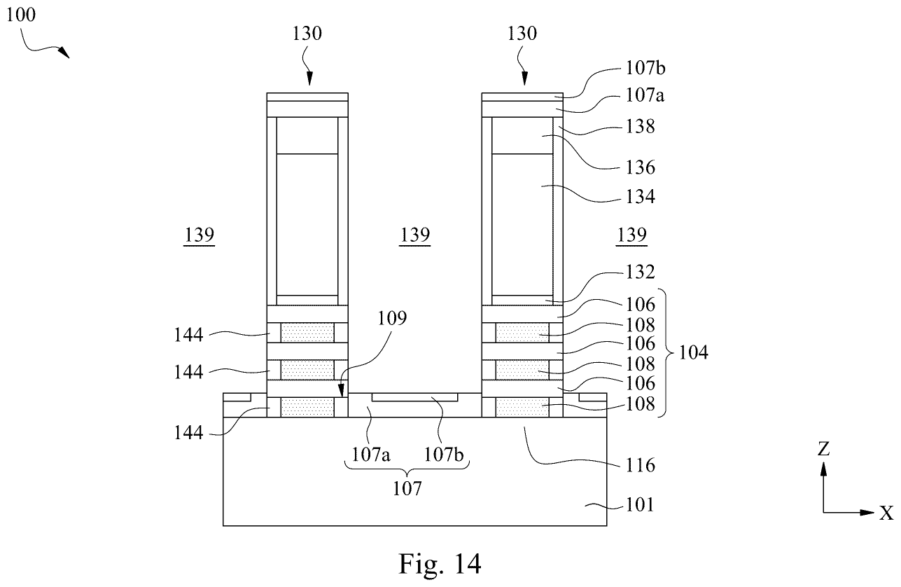

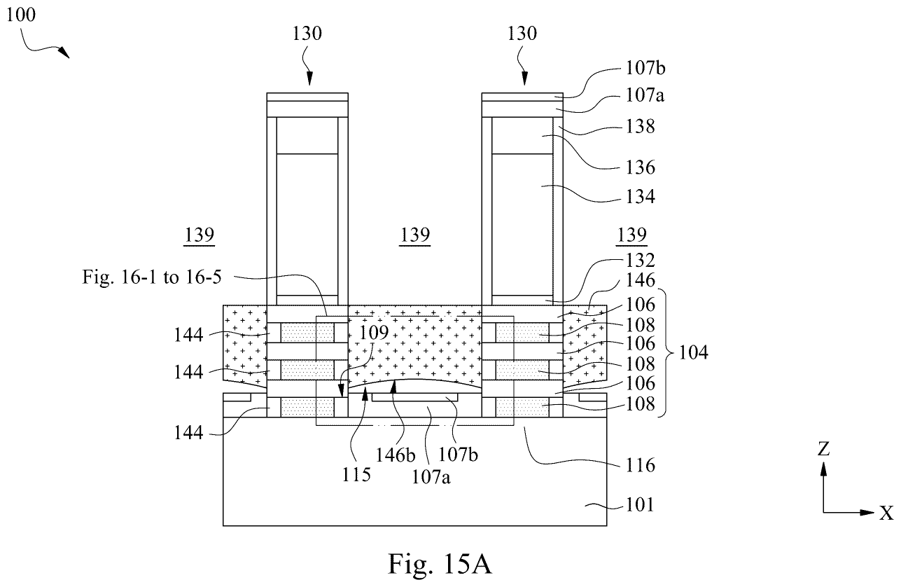

At block 1028, a pre-clean process is performed to remove the first dielectric layer 107a over the sidewall surface of the sacrificial gate structures 130, as shown in FIG. 14. The pre-clean process may use an etchant that selectively removes the first dielectric layer 107a without substantially affecting the inner spacers 144. Upon removal of the first dielectric layer 107a over the sidewall surface of the sacrificial gate structures 130, the recess 139 is revealed, and the gate spacers 138, the first semiconductor layers 106, and the inner spacers 144 are exposed. The first and second dielectric layers 107a, 107b over the top surface of the substrate 101 form a dielectric layer structure 107. The pre-clean process may be any suitable wet etch process, such as the wet etch discussed above with respect to the etch process 175-1. In some embodiments, the pre-clean may use a diluted HF solution. The first and second dielectric layers 107a, 107b over the top surface of the substrate 101 may be slightly etched while removing the first dielectric layer 107a from the sidewall surface of the sacrificial gate structures 130. The pre-clean process may enhance the etch profile of the first and second dielectric layers 107a, 107b over the top surface of the substrate 101, as will be discussed in more detail in FIGS. 16-1 to 16-5.

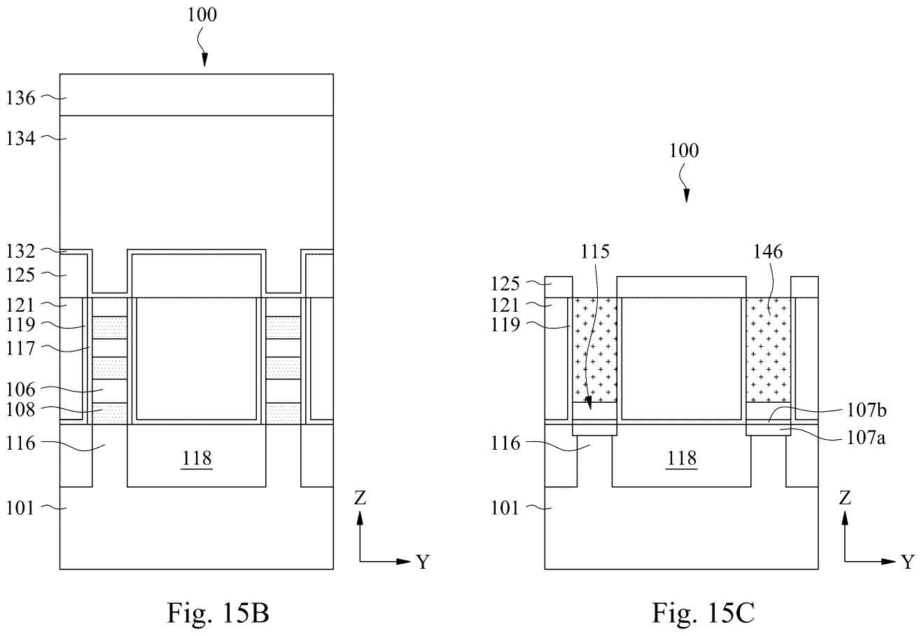

At block 1030, an epitaxial S/D feature 146 is formed in the source/drain (S/D) regions, as shown in FIGS. 15A-15C. The second semiconductor layer 108 under the sacrificial gate structure 130 are separated from the epitaxial S/D features 146 by the inner spacers 144. The epitaxial S/D feature 146 may include one or more layers of Si, SiP, SiC and SiCP for an n-type FET or Si, SiGe, Ge for a p-type FET. The epitaxial S/D features 146 may be formed by an epitaxial growth method using selective epitaxial growth (SEG), CVD, ALD or MBE. The epitaxial S/D features 146 may be the S/D regions. For example, one of a pair of epitaxial S/D features 146 located on one side of the sacrificial gate structures 130 may be a source region, and the other of the pair of epitaxial S/D features 146 located on the other side of the sacrificial gate structures 130 may be a drain region. A pair of S/D epitaxial features 146 includes a source epitaxial feature 146 and a drain epitaxial feature 146 connected by the channels (i.e., the first semiconductor layers 106). Source/drain region(s) may refer to a source or a drain, individually or collectively dependent upon the context. In this disclosure, a source and a drain are interchangeably used, and the structures thereof are substantially the same.

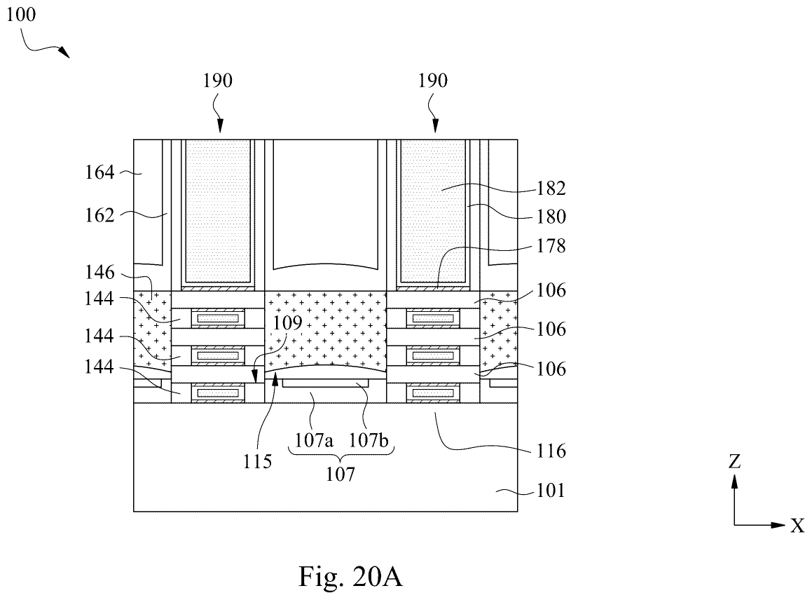

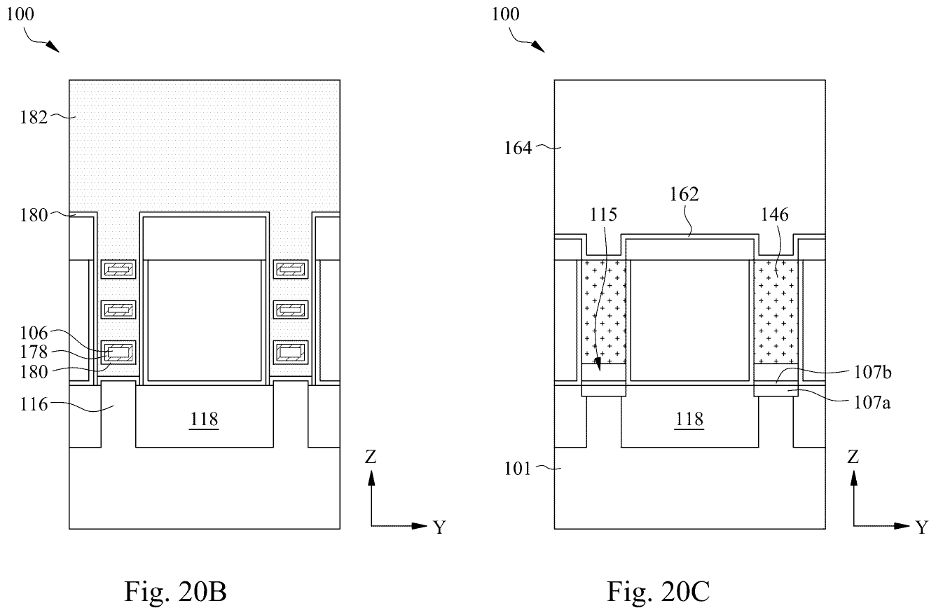

The epitaxial S/D features 146 may grow laterally from the sidewall of the first semiconductor layers 106. The epitaxial S/D features 146 of a fin structure may merge with the epitaxial S/D features 146 of the neighboring fin structures and form an integrated body. The epitaxial S/D features 146 may grow both vertically and horizontally to form facets, which may correspond to crystalline planes of the material used for the first semiconductor layers 106. Since the semiconductor (i.e., epitaxial S/D features 146) may not grow, or does not grow well on the dielectric material (e.g., first and second dielectric layers 107a, 107b), a bottom portion of the epitaxial S/D feature 146 may separate from the first and second dielectric layers 107a, 107b by an air gap 115. The air gap 115 can effectively reduce capacitance between the epitaxial source/drain feature 146 and the subsequent gate electrode layer (e.g., gate electrode layer 182, FIG. 20A) in the replacement gate structure. In some embodiments, the bottom surface 146b of each epitaxial S/D feature 146 may have a curved surface, such as a concave shape.

FIGS. 16-1 to 16-5 illustrate an enlarged view of a portion of the semiconductor device structure 100 of FIG. 15A, in accordance with some embodiments. In FIG. 16-1, the epitaxial S/D feature 146 is disposed above the first and second dielectric layers 107a, 107b. The first dielectric layer 107a is disposed in (or nested within) the second dielectric layer 107b and has its sidewall surfaces and a bottom surface in contact with the second dielectric layer 107b. In some embodiments, the top surface 107at of the first dielectric layer 107a and the top surface 107bt of the second dielectric layer 107b are substantially co-planar. The epitaxial S/D feature 146 is disposed between and in contact with two neighboring first semiconductor layers 106 and inner spacers 144. The bottom surface 146b of the epitaxial S/D feature 146 may have a curved surface which separates the epitaxial S/D feature 146 from the first and second dielectric layers 107a, 107b by the air gap 115. The air gap 115 is confined by the epitaxial S/D feature 146, the top surface 107at of the first dielectric layer 107a, the top surface 107bt of the second dielectric layer 107b.

In some embodiments, the top surface 107bt of the second dielectric layer 107b is separated from the bottom surface 146b of the epitaxial S/D feature 146 by a vertical distance D1, and the top surface 107at of the first dielectric layer 107a is separated from the bottom surface 146b of the epitaxial S/D feature 146 by a vertical distance D2, which is less than the vertical distance D1.

In some embodiments, the epitaxial S/D feature 146 does not contact the first dielectric layer 107a. In some embodiments, an edge portion of the epitaxial S/D feature 146 may be in slight contact with the first dielectric layer 107a, as shown in FIG. 16-1a. In some embodiments, an edge portion of the epitaxial S/D feature 146 is in contact with the first dielectric layer 107a but not the second dielectric layer 107b. In some embodiments, an edge portion of the epitaxial S/D feature 146 is in contact with the inner spacer 144, without touching the first and second dielectric layers 107a, 107b, as shown in FIG. 16-1b. In this embodiment, the air gap 115 is confined by the epitaxial S/D feature 146, the top surface 107at of the first dielectric layer 107a, the top surface 107bt of the second dielectric layer 107b, and the sidewall surface of the inner spacer 144.

FIG. 16-2 illustrates an embodiment similar to the embodiment of FIG. 16-1 except that the top surface 107at of the first dielectric layer 107a and the top surface 107bt of the second dielectric layer 107b are at different heights. For example, the top surface 107at of the first dielectric layer 107a may be at an elevation higher than the top surface 107bt of the second dielectric layer 107b. In some embodiments, the top surface 107at of the first dielectric layer 107a may be at an elevation lower than the top surface 107bt of the second dielectric layer 107b.

FIG. 16-3 illustrates an embodiment similar to the embodiment of FIG. 16-2 except that the top surface 107bt of the second dielectric layer 107b has a curved surface (e.g., concave profile), which may be formed as a result of an isotropic etchant used by the etch process 175-1. In this embodiment, the highest point of the second dielectric layer 107b, such as the peripheral edge of the top surface 107bt of the second dielectric layer 107b, is lower than the top surface 107at of the first dielectric layer 107a.

FIG. 16-4 illustrates an embodiment similar to the embodiment of FIG. 16-3 except that the substrate 101 between neighboring replacement gate structures 190 has a curved (e.g., convex) top surface 101t. In such cases, the first dielectric layer 107a deposited thereon may have a curved bottom surface that follows the curved profile of the top surface 101t of the substrate 101. After formation of the recess 139 (FIG. 9A), the top surface 101t of the substrate 101 may be etched to have a concave profile. In some cases, a deposition process may be performed to redeposit the material (e.g., silicon) on the concave top surface so that the top surface 101t of the substrate 101 has a convex profile. The first dielectric layer 107a thus follows the convex profile of the substrate 101. In some embodiments, the top surface 107at of the first dielectric layer 107a may also have a curved profile (e.g., convex). In such cases, the top surface 107at of the first dielectric layer 107a may have a first curvature, and the top surface 107bt of the second dielectric layer 107b may have a second curvature that is different than the first curvature. In some embodiments, the first curvature is greater than the second curvature. In some embodiments, the top surfaces 107at, 107bt of the first and second dielectric layers 107a, 107b have a curved profile that is opposite to the top surface 101t of the substrate 101, as shown in FIG. 16-4.

FIG. 16-5 illustrates an embodiment similar to the embodiment of FIG. 16-4 except that the first and second dielectric layers 107a, 107b have a profile that follows the top surface 101t of the substrate 101. In embodiments where the top surface 101t of the substate 101 has a curved (e.g., convex) profile, the first and second dielectric layers 107a, 107b are deposited to have a curved (e.g., convex) profile. In some embodiments, the highest point of the second dielectric layer 107b may be at an elevation lower than the top surface 107at of the first dielectric layer 107a. In some embodiments, the highest point of the second dielectric layer 107b may be at an elevation higher than the top surface 107at of the first dielectric layer 107a.

While not shown in the embodiments of FIGS. 16-2 to 16-5, it is contemplated that in some embodiments the top surface 107bt of the second dielectric layer 107b is separated from the bottom surface 146b of the epitaxial S/D feature 146 by a first vertical distance, and the top surface 107at of the first dielectric layer 107a is separated from the bottom surface 146b of the epitaxial S/D feature 146 by a second vertical distance that is less than the first vertical distance.

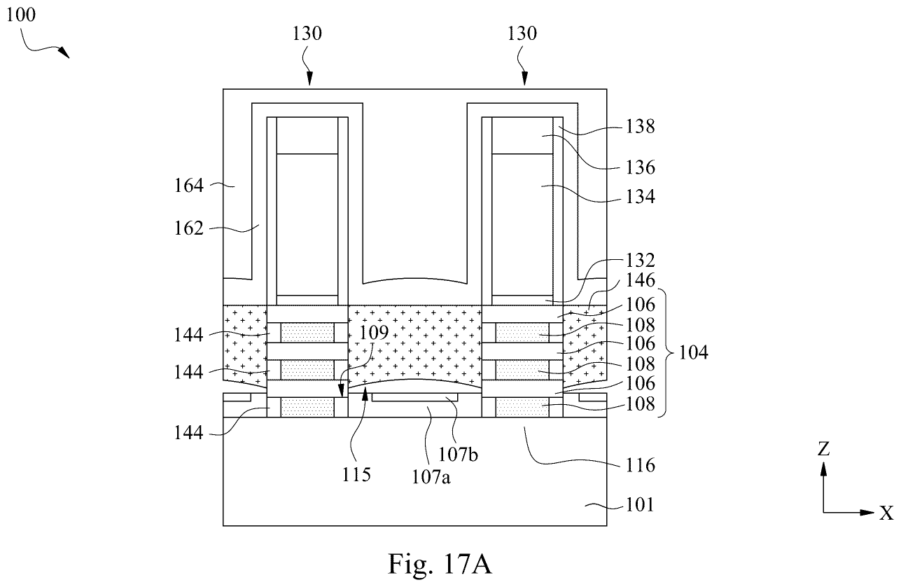

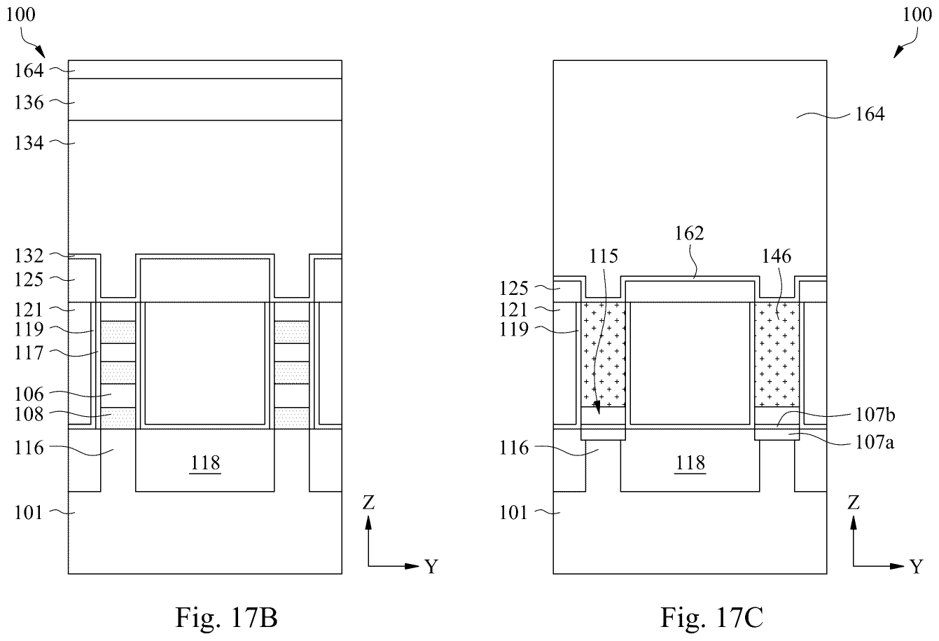

At block 1032, a contact etch stop layer (CESL) 162 is conformally formed on the exposed surfaces of the semiconductor device structure 100, as shown in FIGS. 17A-17C. The CESL 162 covers the top surfaces of the sacrificial gate structure 130, the insulating material 118, and the epitaxial S/D features 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, an interlayer dielectric (ILD) layer 164 is formed on the CESL 162 over the semiconductor device structure 100. The materials for the ILD layer 164 may include compounds comprising Si, O, C, and/or H, such as silicon oxide, TEOS oxide, SiCOH and SiOC. Organic materials, such as polymers, may also be used for the ILD layer 164. The ILD layer 164 may be deposited by a PECVD process or other suitable deposition technique.

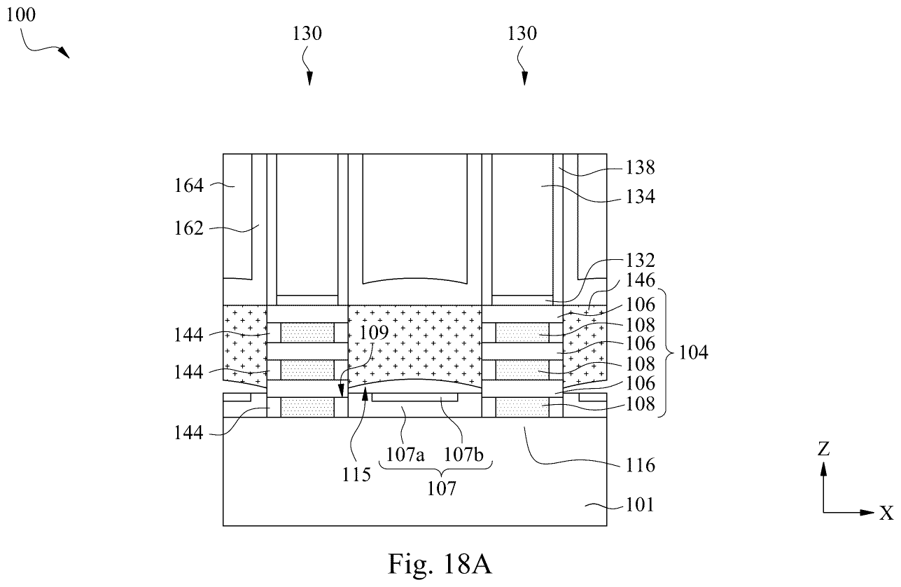

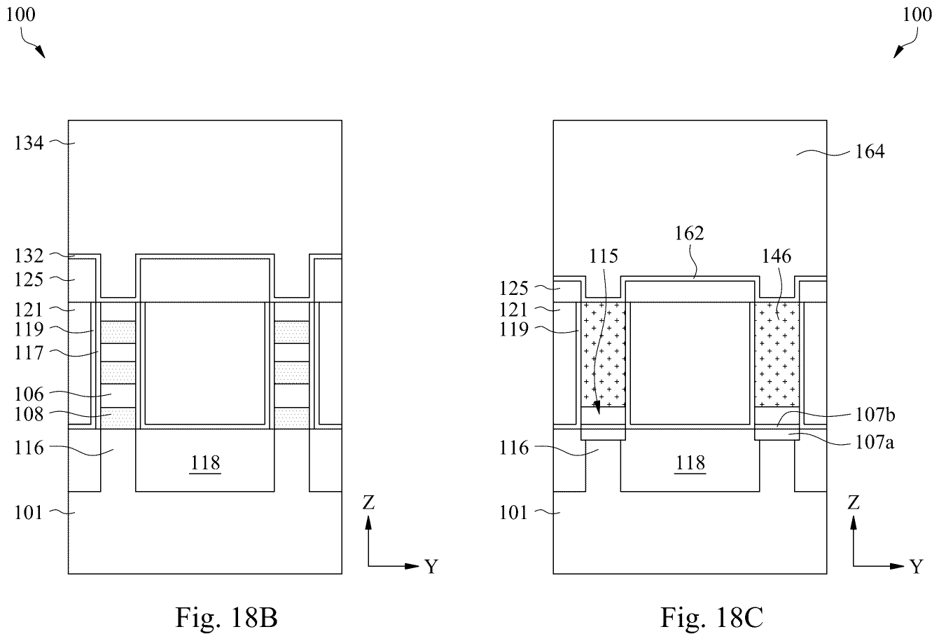

At block 1034, after the ILD layer 164 is formed, a planarization operation, such as CMP, is performed on the semiconductor device structure 100 until the sacrificial gate electrode layer 134 is exposed, as shown in FIG. 18A-18C.

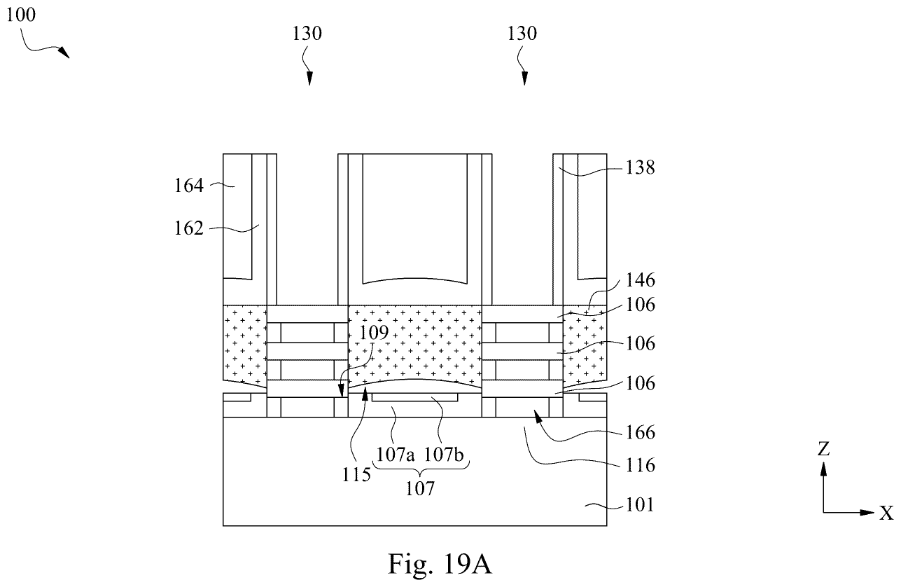

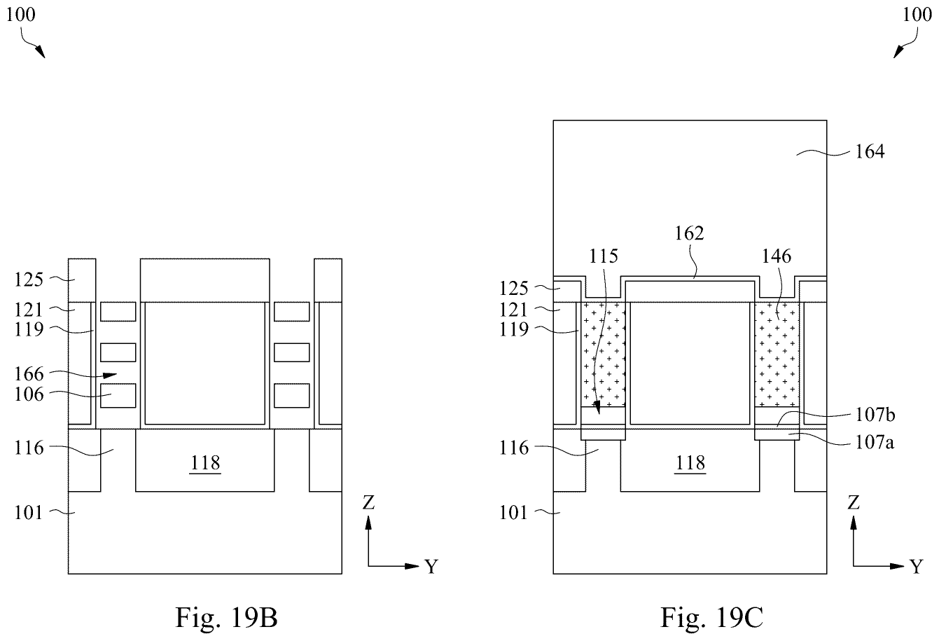

At block 1036, the sacrificial gate structure 130 and the second semiconductor layers 108 are sequentially removed, as shown in FIGS. 19A-19C. The removal of the sacrificial gate structure 130 and the semiconductor layers 108 forms an opening 166 between gate spacers 138 and between adjacent first semiconductor layers 106. The ILD layer 164 protects the epitaxial S/D features 146 during the removal processes. The sacrificial gate structure 130 can be removed using plasma dry etching and/or wet etching. The sacrificial gate electrode layer 134 may be first removed by any suitable process, such as dry etch, wet etch, or a combination thereof, followed by the removal of the sacrificial gate dielectric layer 132, which may also be performed by any suitable process, such as dry etch, wet etch, or a combination thereof.

The removal of the sacrificial gate structure 130 exposes the first semiconductor layers 106 and the second semiconductor layers 108. An etch process, which may be any suitable etch processes, such as dry etch, wet etch, or a combination thereof, is then performed to remove the second semiconductor layers 108 and expose the inner spacers 144. The etch process may be a selective etch process that removes the second semiconductor layers 108 but not the gate spacers 138, the inner spacers 144, the ILD layer 164, the CESL 162, and the first semiconductor layers 106. In one embodiment, the second semiconductor layers 108 can be removed using a wet etchant such as, but not limited to, hydrofluoric (HF), nitric acid (HNO₃), hydrochloric acid (HCl), phosphoric acid (H₃PO₄), a dry etchant such as fluorine-based (e.g., F₂) or chlorine-based gas (e.g., Cl₂), or any suitable isotropic etchants. After the etch process, a portion of the first semiconductor layers 106 not covered by the inner spacers 144 is exposed through the opening 166.

At block 1038, replacement gate structures 190 are formed, as shown in FIGS. 20A-20C. Each replacement gate structure 190 may include an interfacial layer (IL) 178, a gate dielectric layer 180, and a gate electrode layer 182. The interfacial layer (IL) 178 is formed to surround exposed surfaces of the first semiconductor layers 106 along the channel regions. The IL 178 may include or be made of an oxide (e.g., silicon oxide) formed by thermal or chemical oxidation of the first semiconductor layers 106, a nitride (e.g., silicon nitride, silicon oxynitride, oxynitride, etc.), and/or a dielectric layer (e.g., hafnium silicate). The IL 178 may be formed by CVD, ALD, a clean process, or any suitable process. Next, the gate dielectric layer 180 is formed on the exposed surfaces of the semiconductor device structure 100 (e.g., on the IL 178, sidewalls of the gate spacers 138, the top surfaces of the first ILD layer 164, the CESL 162, and the inner spacers 144). The gate dielectric layer 180 may include or made of a high-k dielectric material, such as hafnium oxide (HfO₂), hafnium silicate (HfSiO), hafnium silicon oxynitride (HfSiON), hafnium aluminum oxide (HfAIO), hafnium lanthanum oxide (HfLaO), hafnium zirconium oxide (HfZrO), hafnium tantalum oxide (HfTaO), hafnium titanium oxide (HfTiO), lanthanum oxide (LaO), aluminum oxide (AIO), aluminum silicon oxide (AlSiO), zirconium oxide (ZrO), titanium oxide (TiO), tantalum oxide (Ta₂O₅), yttrium oxide (Y₂O₃), silicon oxynitride (SiON), or other suitable high-k materials. The gate dielectric layer 180 may be a conformal layer formed by a conformal process, such as an ALD process, a PECVD process, a molecular-beam deposition (MBD) process, or the like, or a combination thereof.

After formation of the IL 178 and the gate dielectric layer 180, the gate electrode layer 182 is formed on the gate dielectric layer 180. The gate electrode layer 182 filles the openings 166 (FIGS. 19A and 19B) and surrounds a portion of each of the first semiconductor layers 106. The gate electrode layer 182 includes one or more layers of conductive material, such as polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. The gate electrode layers 182 may be formed by PVD, CVD, ALD, electro-plating, or other suitable method. In some embodiments, one or more optional conformal layers (not shown) can be conformally (and sequentially, if more than one) deposited between the gate dielectric layer 180 and the gate electrode layer 182. The one or more optional conformal layers can include one or more barrier and/or capping layers and one or more work-function tuning layers. The one or more barrier and/or capping layers may include or be a nitride, silicon nitride, carbon nitride, and/or aluminum nitride of tantalum and/or titanium; a nitride, carbon nitride, and/or carbide of tungsten; the like; or a combination thereof. The one or more work-function tuning layers may include or be a nitride, silicon nitride, carbon nitride, aluminum nitride, aluminum oxide, and/or aluminum carbide of titanium and/or tantalum; a nitride, carbon nitride, and/or carbide of tungsten; cobalt; platinum; the like; or a combination thereof.

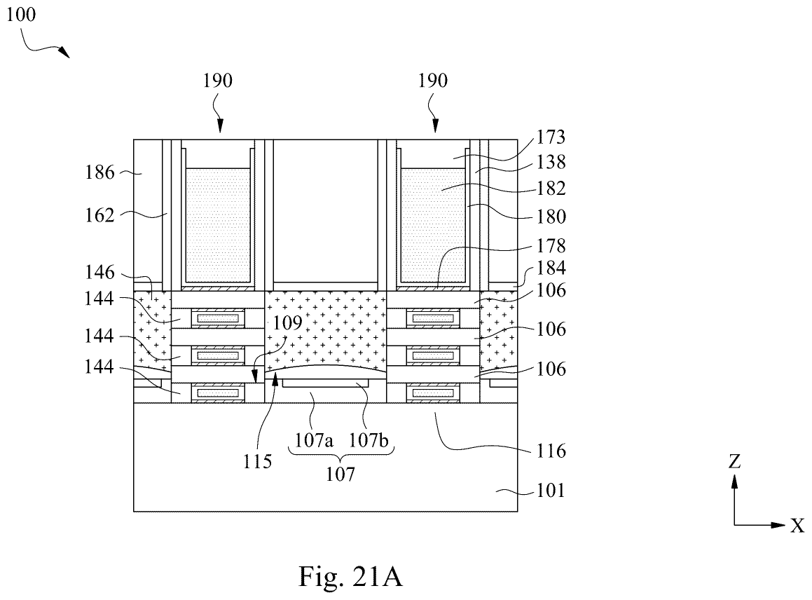

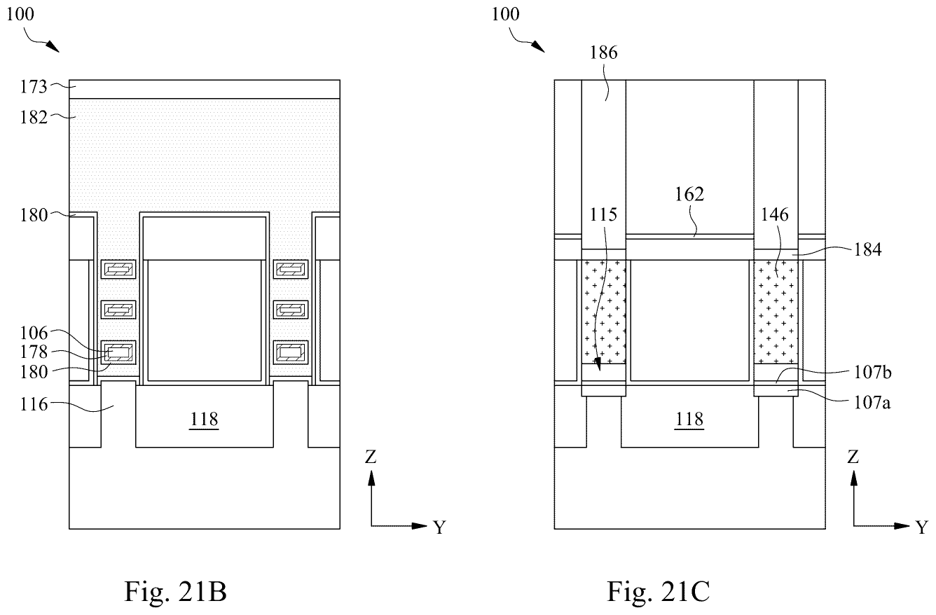

At block 1040, the gate electrode layer 182 may be subject to one or more metal gate etching back (MGEB) processes. The MGEB processes are performed so that the top surfaces of the gate electrode layer 182 and the gate dielectric layer 180 are recessed to a level below the top surface of the gate spacers 138. In some embodiments, the gate spacers 138 are also recessed to a level below the top surface of the ILD layer 164. A self-aligned contact layer 173 is formed over the gate electrode layer 182 and the gate dielectric layer 180 between the gate spacers 138, as shown in FIGS. 21A-21C. The self-aligned contact layer 173 may be a dielectric material having an etch selectivity relative to the ILD layer 164. In some embodiments, the self-aligned contact layer 173 includes silicon nitride.

Then, contact openings are formed through the ILD layer 164, and the CESL 162 to expose the epitaxial S/D feature 146. A silicide layer 184 is then formed on the S/D epitaxial features 146, and a source/drain (S/D) contact 186 is formed in the contact opening on the silicide layer 184. The S/D contact 186 may include an electrically conductive material, such as Ru, Mo, Co, Ni, W, Ti, Ta, Cu, Al, TiN, or TaN. The silicide layer 184 may include a metal or metal alloy silicide, and the metal includes a noble metal, a refractory metal, a rare earth metal, alloys thereof, or combinations thereof. Next, a conductive material is formed in the contact openings and form the S/D contacts 186, as shown in FIGS. 21A and 21B. The conductive material may be made of a material including one or more of Ru, Mo, Co, Ni, W, Ti, Ta, Cu, Al, TiN and TaN. While not shown, a barrier layer (e.g., TiN, TaN, or the like) may be formed on sidewalls of the contact openings prior to forming the S/D contacts 186. Then, a planarization process, such as CMP, is performed to remove excess deposition of the contact material and expose the top surface of the gate electrode layer 182.

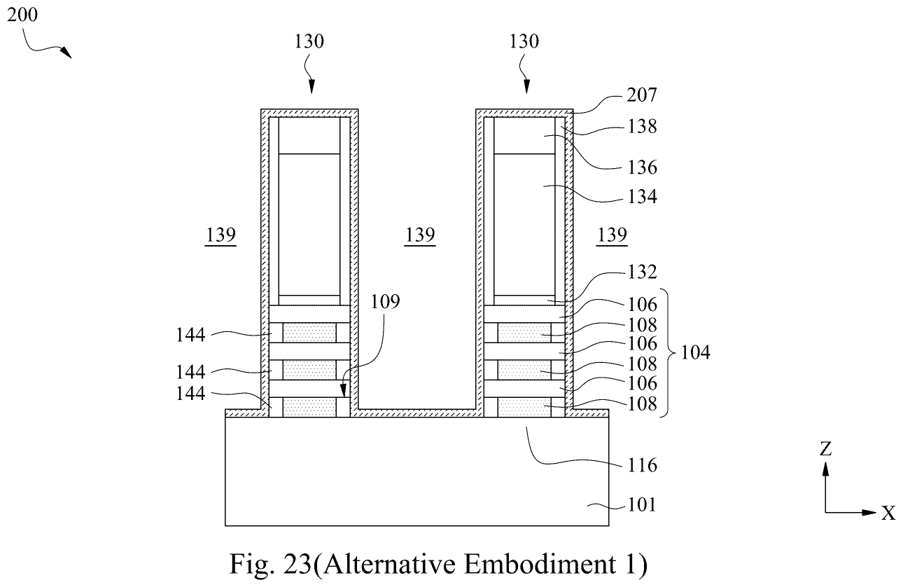

FIGS. 23-27 illustrate a semiconductor device 200 at various stages of fabrication in accordance with some alternative embodiments. In the embodiment shown in FIG. 23, which shows a stage after the recess 139 is formed (e.g., FIGS. 9A and 9C), a dielectric layer 207, such as the first dielectric layer 107a, is formed on exposed surfaces of the sacrificial gate structures 130, the stack of semiconductor layers 104, and the substrate 101. The dielectric layer 207 may be conformally formed on the top surface and sidewall surfaces of the sacrificial gate structures 130. Similar to the first dielectric layer 107a, the dielectric layer 207 serves as a protection layer to prevent source/drain leakage and parasitic capacitance between source/drain features and gate. The dielectric layer 207 may include the same material as the first dielectric layer 107a, and may be formed by the same deposition technique used for the first dielectric layer 107a.

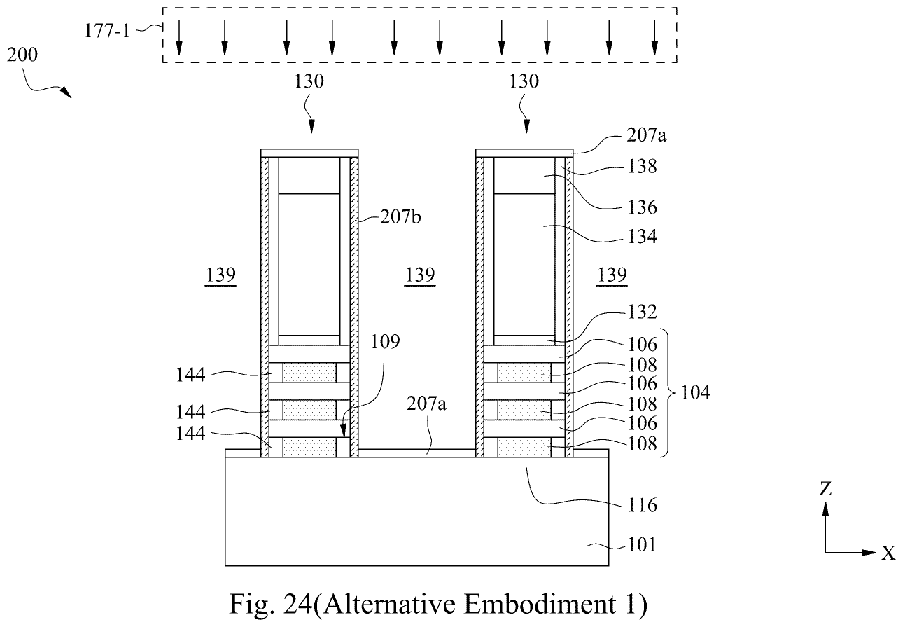

In FIG. 24, the dielectric layer 207 is subjected to a treatment process 177-1 to convert a portion of the dielectric layer 207 into a modified layer. In various embodiments, the treatment process 177-1 may be anisotropic so that the dielectric layer 207 on the horizontal surfaces (e.g., top surface of the sacrificial gate structures 130 and the top surface of the substrate 101) is converted to a first modified layer 207a having a first film property (e.g., higher film density, growth rate, etch rate, or the like), and the dielectric layer 207 on the vertical surfaces (e.g., the sidewall surfaces of the sacrificial gate structures 130 and the stack of semiconductor layers 104) is converted to a second modified layer 207b having a second film property that is different than the first film property. In some embodiments, the first modified layer 207a may have a higher film density and lower etch rate than that of the second modified layer.

In some embodiments, the treatment process 177-1 may be a nitridation process using plasma or a radical of species. For example, the treatment process 177-1 may use reactive species generated from nitrogen-containing gases in-situ in a reaction chamber or in the upstream of a reaction chamber (e.g., from a remote plasma generator). In some embodiments, the treatment process 177-1 is a plasma treatment process. Exemplary reactive species may include nitrogen plasma or neutral radical species of nitrogen, such as nitrogen radicals or atomic nitrogen. The plasma treatment may be any suitable plasma process, such as a decoupled plasma process, a remote plasma process, or a combination thereof. The plasma may be formed by a CCP source or an ICP source driven by an RF power generator. In some embodiments, the plasma is a microwave-induced plasma with high frequency or low frequency bias. The dielectric layer 207 is nitridized or becomes a nitridized region (i.e., first and second modified layer 207a, 207b) after the treatment process 177-1. In cases where the dielectric layer 207 is formed of silicon oxide, the first and second modified layer 207a, 207b may be partially or fully converted into silicon oxynitride.

In cases where ICP source is used, the treatment process 177-1 may be performed in a remote plasma generator. Likewise, the plasma source power may use a continuous wave RF power generator or a pulsed RF power generator operating on a predetermined duty cycle. The source power ionizes the nitrogen-containing gases supplied to the remote plasma generator. The generated nitrogen ions may be filtered to generate neutral radical species (e.g., nitrogen radicals) prior to supplying to the process chamber in which the semiconductor device structure 200 is disposed. In one exemplary embodiment, the decoupled plasma process is formed by the ICP source driven by the RF power generator using a tunable frequency ranging from about 2 MHz to about 13.56 MHz, and the chamber is operated at a pressure in a range of about 0.5 Torr to about 8 Torr and a temperature of about 300 degrees Celsius to about 600 degrees Celsius for a process time of about 3 seconds to about 50 seconds. The flow of the processing gas (e.g., nitrogen-containing gas) may be provided at about 200 sccm to about 5000 sccm. Suitable nitrogen-containing gas may include, but is not limited to, nitrogen gas (N₂), ammonia (NH₃), nitrous oxide (N₂O), or the like. The RF power generator is operated to provide power between about 50 watts to about 1000 watts, and the output of the RF power generator is controlled by a pulse signal having a duty cycle in a range of about 20% to about 80%.

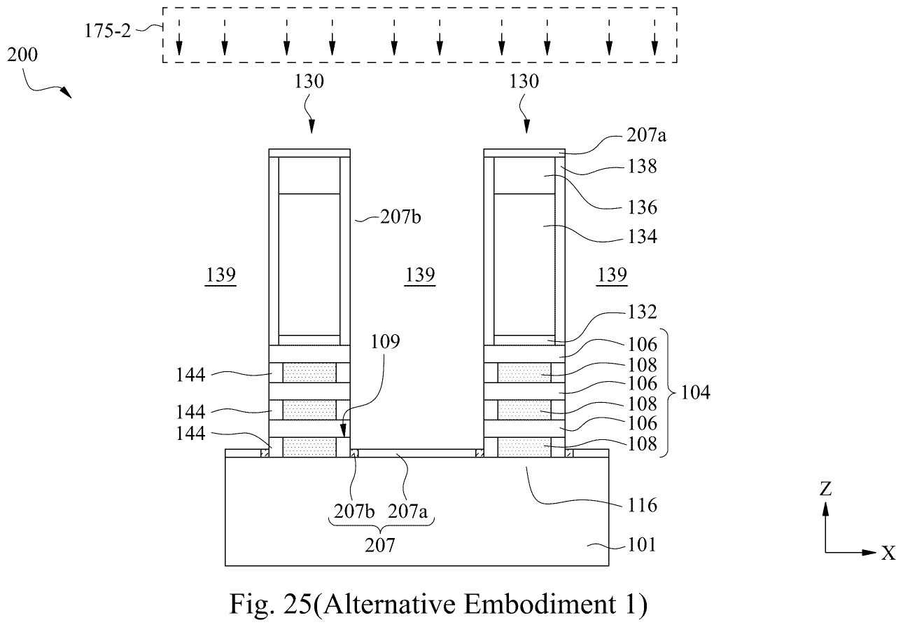

In FIG. 25, the semiconductor device structure 200 is subjected to an etch process 175-2, such as the etch process 175-1, to remove a portion of the dielectric layer 207 (e.g., second modified layer 207b). The etch process 175-2 may be performed in an anisotropic manner such that the first dielectric layers 107a over the sidewall surfaces of the sacrificial gate structures 130 and the stack of semiconductor layers 104 fully removed. The inner spacers 144 are exposed after the second modified layer 207b is removed. The first and second modified layers 207a, 207b on the top surface of the substrate 101 form a dielectric layer structure 207c. In some cases, the second modified layer 207b is removed at a faster rate than the first modified layer 207a, and the second modified layer 207b is removed at a faster rate than the inner spacers 144. The etch process 175-2 may continue until the second modified layer 207b is fully removed. The inner spacers 144 remain substantially intact after the etch process 175-2.

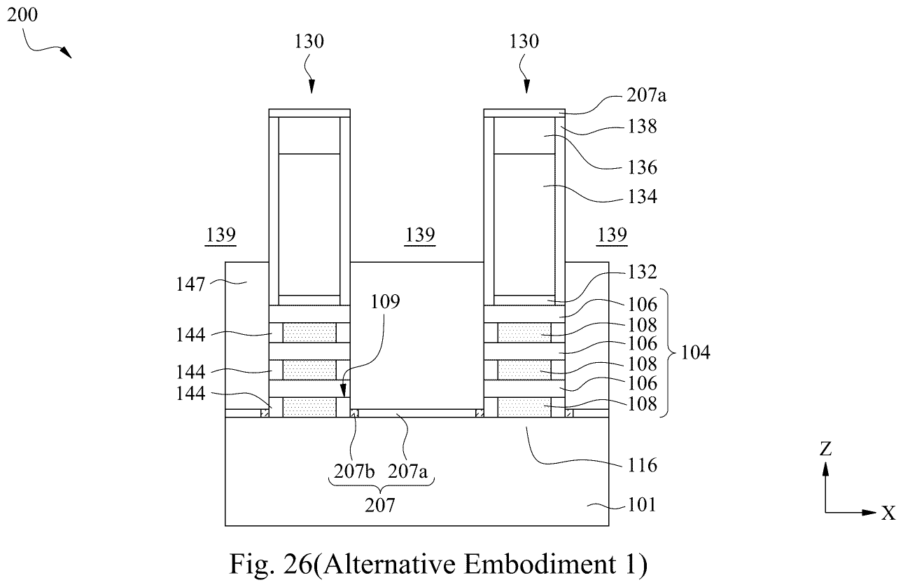

In FIG. 26, a protection layer 147 is formed on the semiconductor device structure 100. The protection layer 147 may be a polymer, a spin-on carbon material, or other suitable photoresist layer. In one embodiment, the protection layer 147 is a carbon-based polymer. The protection layer 147 protects the first and second modified layers 207a, 207b from being damaged during the subsequent etch back process. The protection layer 147 may be deposited until it overfills the recess 139 (FIG. 25) between the neighboring sacrificial gate structures 130. The protection layer 147 may be deposited using a spin-on coating or any suitable deposition process. Then, an etch back process is performed to remove a portion of the protection layer 147. The protection layer 147 may be recessed so that a top surface of the protection layer 147 is at an elevation between the interface 109 defined by the bottommost first semiconductor layer 106 and bottommost inner spacer 144 and an interface defined by the gate spacer 138 and the topmost first semiconductor layer 106. In some embodiments, the protection layer 147 is recessed so that a top surface of the protection layer 147 is high enough to cover the first and second modified layers 207a, 207b. Alternatively, the protection layer 147 may be recessed to any desired height so long as the first modified layer 207a over the sacrificial gate structure 130 is exposed. The etch back process may be a wet etch, a dry etch, or a combination thereof. The etch back process may also remove a portion of the first modified layer 207a over the sacrificial gate structure 130.

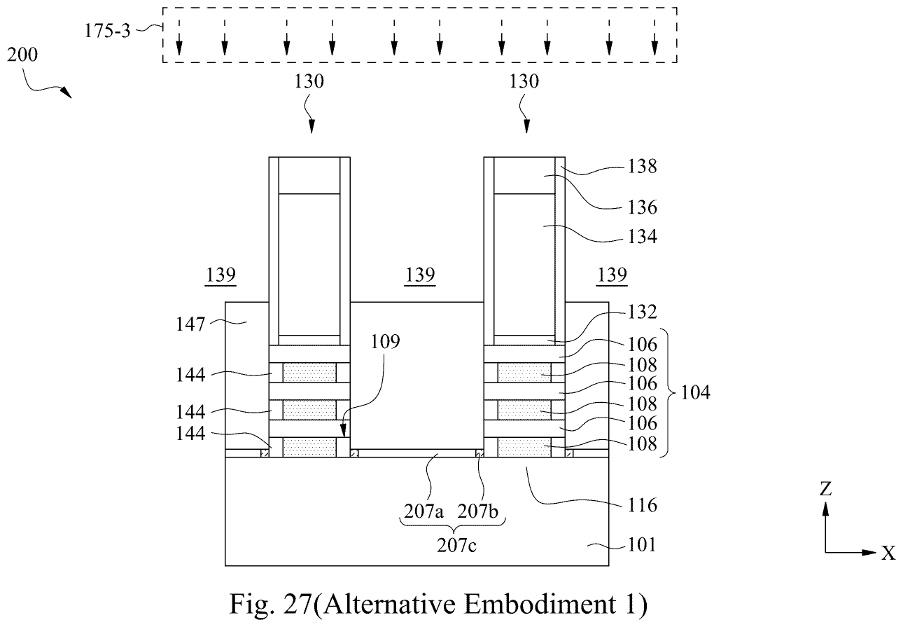

In FIG. 27, the semiconductor device structure 200 is subjected to an etch process 175-3 to remove the first modified layer 207a not covered by the protection layer 147. The etch process 175-3 may be a dry etch, a wet etch, or a combination thereof. The etch process 175-3 may be performed in an isotropic or anisotropic manner. After the etch process 175-3, the top surface of the sacrificial gate structure 130 is exposed. The removal of the first modified layer 207a from the top surface of the sacrificial gate structure 130 may be advantageous as it prevents unwanted merging of the first modified layer 207a on the two neighboring sacrificial gate structures 130, or narrowing of the opening of the recess 139 that may result in formation of a seam in the subsequent interlayer dielectric (ILD) layer 164 and thus degradation of the performance of the device.

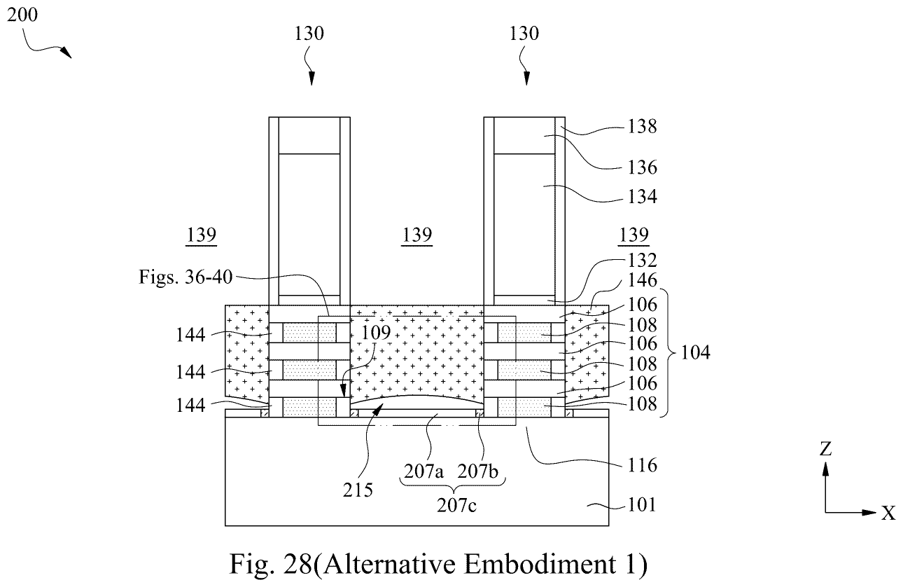

In FIG. 28, the protection layer 147 is removed and epitaxial S/D features 146 are formed. The protection layer 147 may be removed using any suitable process, such as an ashing process or any suitable process. The epitaxial S/D features 146 may be formed using the same process as discussed above with respect to FIGS. 15A-15C. Since the semiconductor (i.e., epitaxial S/D features 146) may not grow, or does not grow well on the dielectric material (e.g., first and second modified layers 207a, 207b), a bottom portion of the epitaxial S/D feature 146 may separate from the first and second modified layers 207a, 207b by an air gap 215. The semiconductor device structure 200 may undergo further processes, such as the processes described above with respect to FIGS. 15A-15C and 17A-17C to 21A-21C.

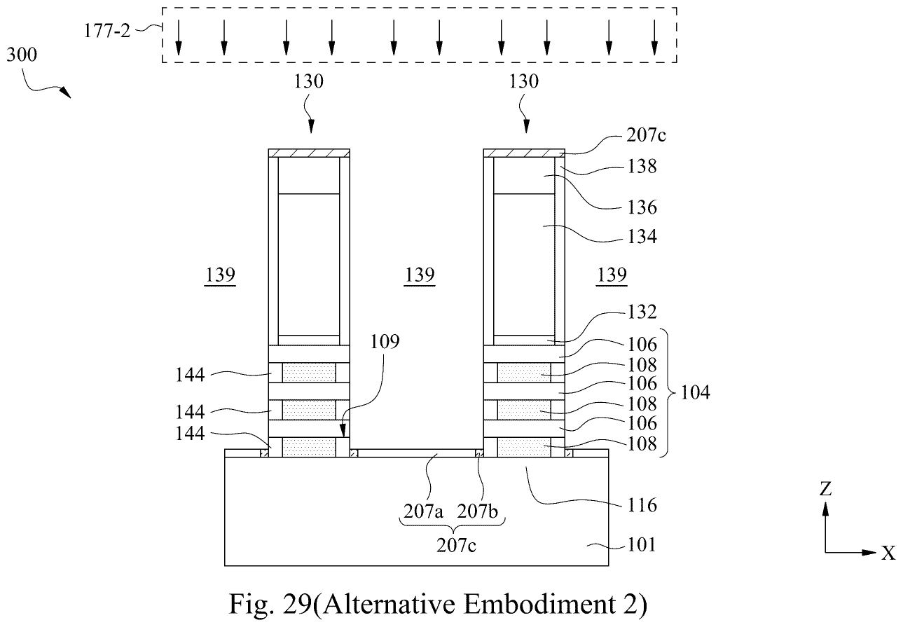

FIGS. 29-31 illustrate a semiconductor device structure 300 at various stages of fabrication in accordance with some alternative embodiments. The semiconductor device structure 300 is substantially identical to the semiconductor device structure 200 shown in FIG. 24 except that FIG. 29 shows a stage after the second modified layer 207b has been removed from the sidewall surfaces of the sacrificial gate structure 130 and the stack of the semiconductor layers 104 (e.g., FIG. 25). As can be seen, the semiconductor device structure 300 is subjected to a treatment process 177-2 to further convert the first modified layer 207a over the top surface of the sacrificial gate structure 130 into a third modified layer 207c having a third film property. The treatment process 177-2 allows easy removal of the third modified layer 207c during the subsequent pre-clean process (for epitaxial S/D features 146). Due to the high aspect-ratio of the recess 139, the first and second modified layers 207a, 207b at the bottom of the recess 139 (e.g., the first and second modified layers 207a, 207b over the top surface of the substrate 101) may have minimum impact from the treatment process 177-2. In most cases, the third film property of the third modified layer 207c is different than the film property possessed by the first and second modified layers 207a, 207b over the top surface of the substrate 101. In some embodiments, the first modified layer 207a may have a higher etch rate than that of the second modified layer 207b, and the etch rate of the first modified layer 207a may have a higher etch rate than that of the inner spacers 144.

The treatment process 177-2 may be a plasma treatment or a treatment using radical of species. For example, the treatment process 177-2 may use reactive species generated from oxygen-containing gases in-situ in a reaction chamber or in the upstream of a reaction chamber (e.g., from a remote plasma generator). Exemplary reactive species may include oxygen plasma or neutral radical species of oxygen, such as oxygen radicals or atomic oxygen. In case a plasma treatment is used, the plasma may be formed by a capacitively coupled plasma (CCP) source, an inductively coupled plasma (ICP) source driven by an RF power generator, or a microwave-induced plasma with ion filter.

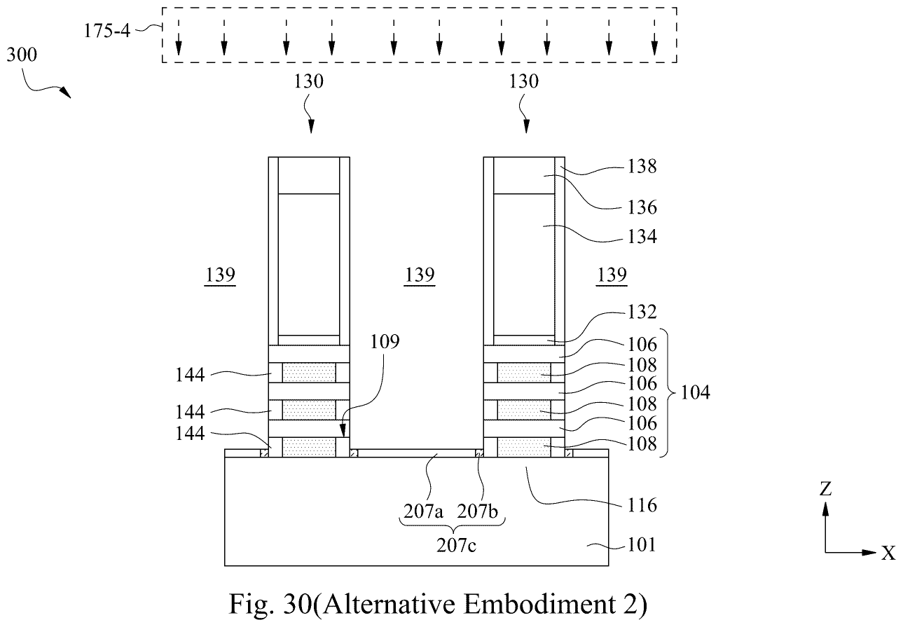

In FIG. 30, an etch process 175-4, such as the etch process 175-1 as discussed above with respect to FIG. 13, is performed to remove the third modified layer 207c from the top surface of the sacrificial gate structure 130. The removal of the first modified layer 207a from the top surface of the sacrificial gate structure 130 may be advantageous as it prevents unwanted merging of the third modified layer 207c on the two neighboring sacrificial gate structures 130, or narrowing of the opening of the recess 139 that may result in formation of a seam in the subsequent interlayer dielectric (ILD) layer 164 and thus degradation of the performance of the device. Due to the high aspect-ratio of the recess 139, the first and second modified layers 207a, 207b at the bottom of the recess 139 (e.g., the first and modified layers 207a, 207b on the top surface of the substrate 101) may have minimum impact from the etch process 175-1.

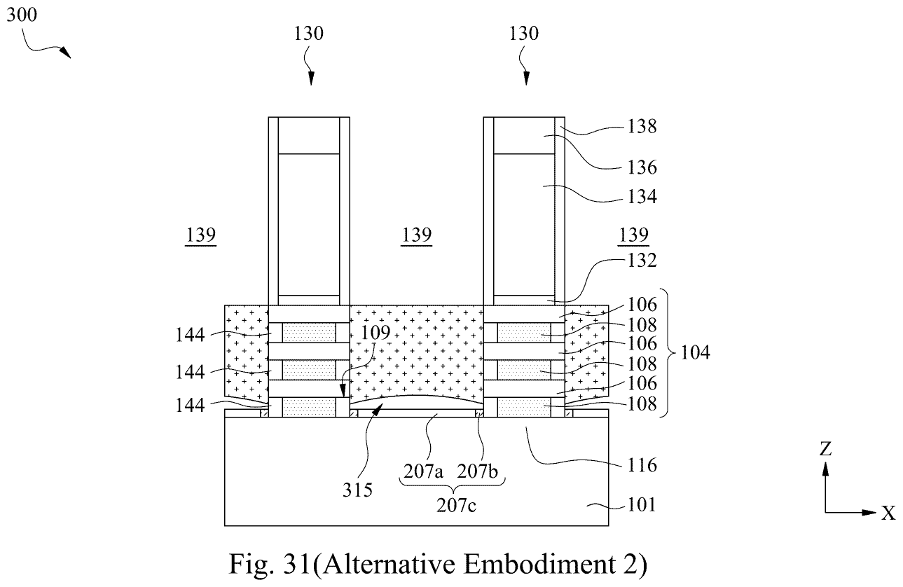

In FIG. 31, the epitaxial S/D features 146 are formed over the first and second modified layers 207a, 207b. The epitaxial S/D features 146 may be formed using the same process as discussed above with respect to FIGS. 15A-15C. Since the semiconductor (i.e., epitaxial S/D features 146) may not grow, or does not grow well on the dielectric material (e.g., first and second modified layers 207a, 207b), a bottom portion of the epitaxial S/D feature 146 may separate from the first and second modified layers 207a, 207b by an air gap 315. Likewise, the semiconductor device structure 300 may undergo further processes, such as the processes described above with respect to FIGS. 15A-15C and 17A-17C to 21A-21C.

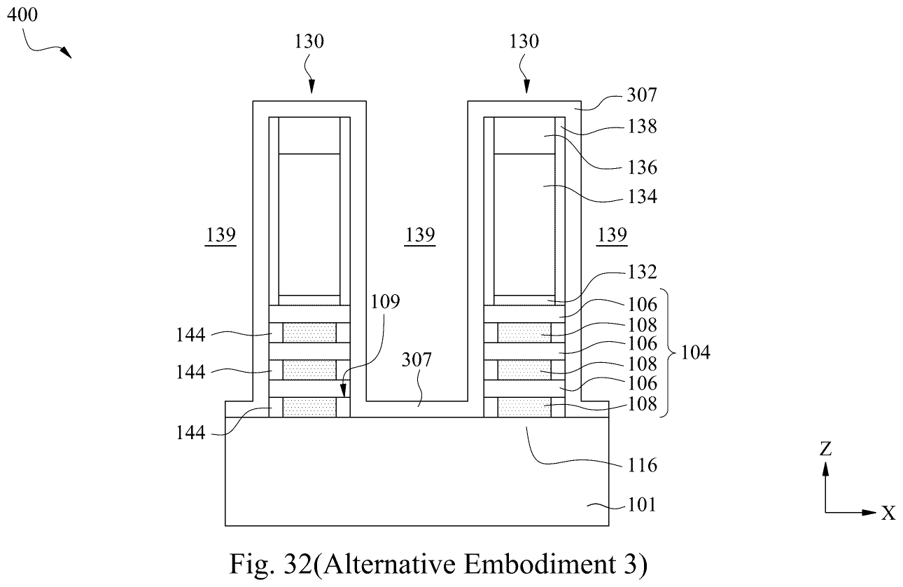

FIGS. 32-35 illustrate a semiconductor device structure 400 at various stages of fabrication in accordance with some alternative embodiments. The semiconductor device structure 400 is similar to the semiconductor device structure 200 shown in FIG. 23, which shows a stage after the recess 139 is formed (e.g., FIGS. 9A and 9C). In FIG. 32, a dielectric layer 307, such as the first dielectric layer 107a, is formed on exposed surfaces of the sacrificial gate structures 130, the stack of semiconductor layers 104, and the substrate 101 in a similar fashion to the first dielectric layer 107a. Likewise, the dielectric layer 307 serves as a protection layer to prevent source/drain leakage and parasitic capacitance between source/drain features and gate.

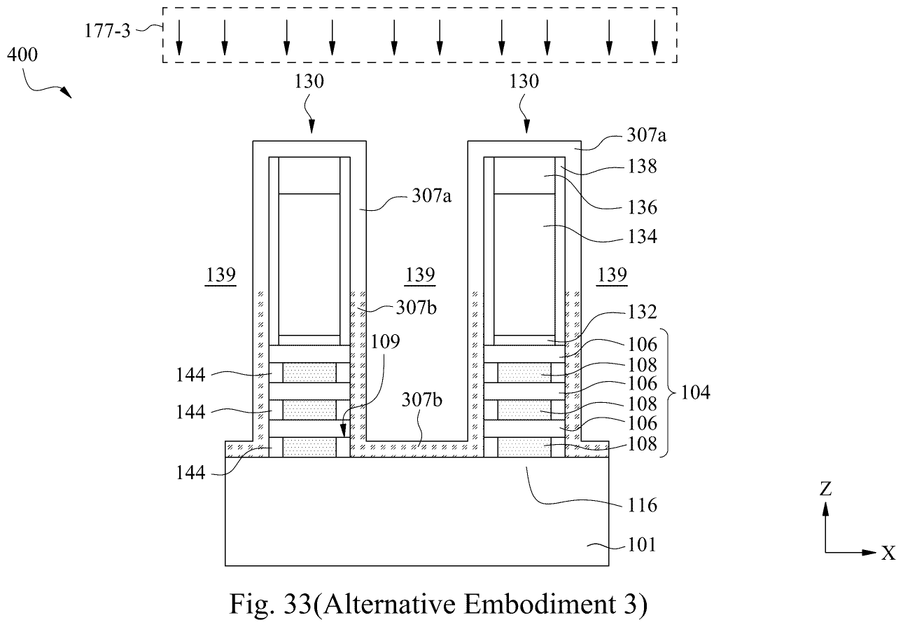

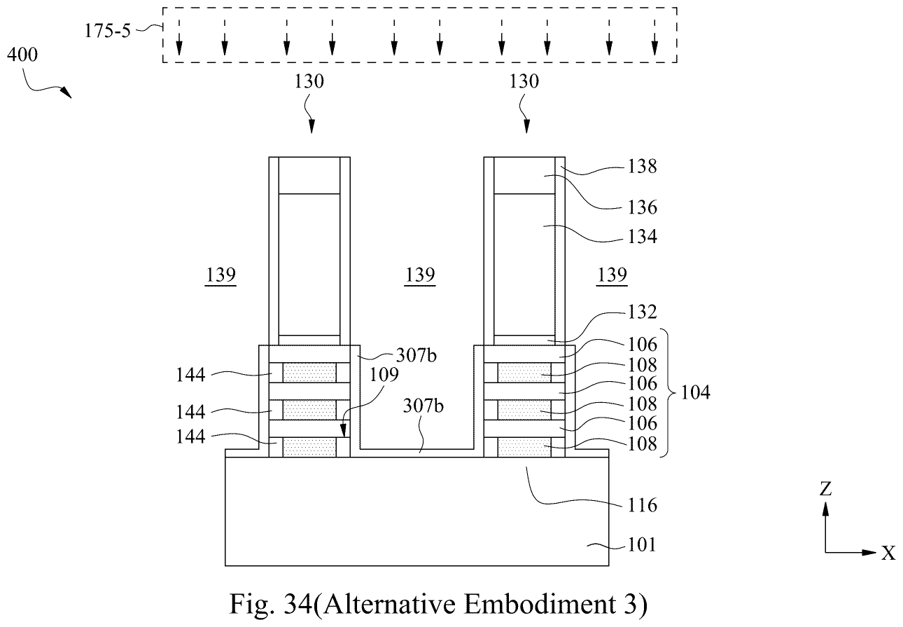

In FIG. 33, the semiconductor device structure 400 is subjected to a treatment process 177-3 so that the dielectric layer 307 has different film properties at different regions. In some embodiments, the treatment process 177-3 is performed such that the dielectric layer 307 over the upper portion of the sacrificial gate structure 130 is converted into a first modified layer 307a having a first film property, and the dielectric layer 307 over the sidewall surface of the stack of semiconductor layers 104 and the top surface of the substrate 101 is converted into a second modified layer 307b having a second film property different than the first film property. Therefore, the treatment process 177-3 creates a difference in etch rates between the first and second modified layers 307a, 307b in order to reduce dishing phenomenon on the inner spacers 144, as discussed above. The treatment process 177-3 also allows easy removal of the first modified layer 307a during the subsequent etch process (FIG. 34). The second modified layer 307b remains substantially intact and protects the inner spacers 144 during the subsequent removal of the first modified layer 307a.

The treatment process 177-3 may be an isotropic plasma or radical of species. For example, the treatment process 177-3 may use reactive species generated from oxygen-containing gases in-situ in a reaction chamber or in the upstream of a reaction chamber (e.g., from a remote plasma generator). Exemplary reactive species may include oxygen plasma or neutral radical species of oxygen, such as oxygen radicals or atomic oxygen. Other reactive species, such as fluorine-based or hydrogen-based plasma, may also be used. In case a plasma treatment is used, the plasma may be formed by a capacitively coupled plasma (CCP) source, an inductively coupled plasma (ICP) source driven by an RF power generator, or a microwave-induced plasma with ion filter.

In FIG. 34, an etch process 175-5, such as the etch process 175-2 as discussed above with respect to FIG. 25, is performed to remove the first modified layer 307a from the upper portion of the sacrificial gate structure 130. A portion of the second modified layer 307b over the sidewall surface of the stack of semiconductor layers 104 and the top surface of the substrate 101 may be etched after the etch process 175-5. The second modified layer 307b protects the inner spacers 144 from being damaged during the etch process 175-5.

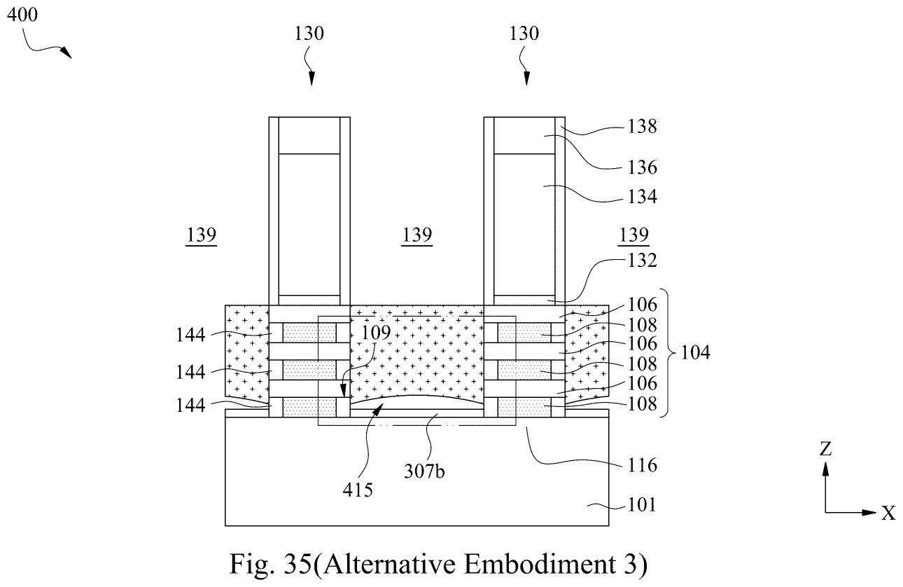

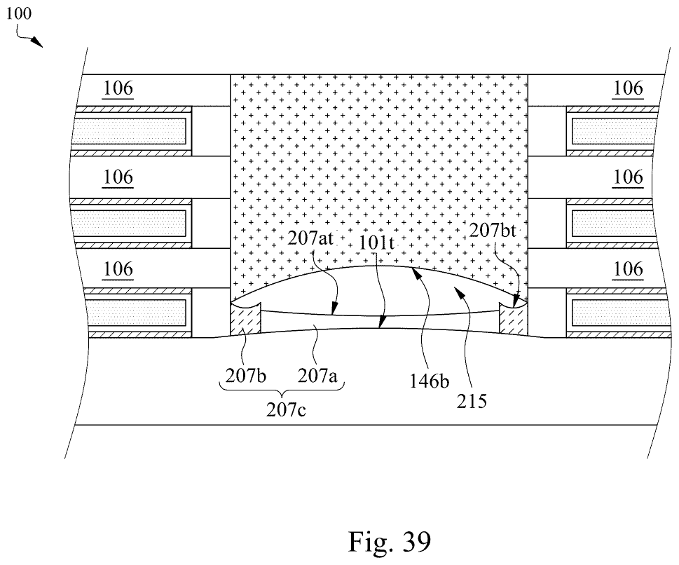

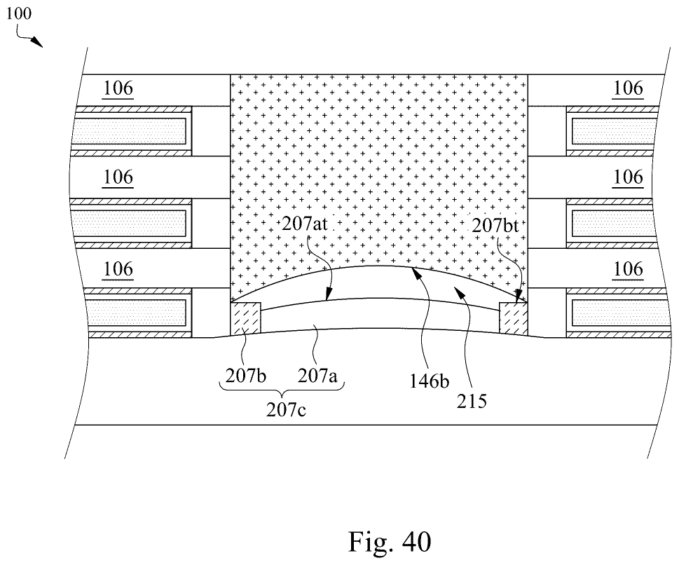

In FIG. 35, a pre-clean process is performed to remove the second modified layer 307b from the sidewall surface of the stack of semiconductor layers 104. Due to the high aspect-ratio of the recess 139, the second modified layer 307b on the top surface of the substrate 101 remains substantially intact. Upon removal of the second modified layer 307b from the sidewall surface of the sacrificial gate structures 130, the recess 139 is revealed, and the inner spacers 144 are exposed. The pre-clean process may use a diluted HF solution or any suitable etch process. The pre-clean process may enhance the etch profile of the second modified layer 307b on the top surface of the substrate 101, as will be discussed in more detail in FIGS. 39-40. After the pre-clean process, the epitaxial S/D features 146 are formed over the second modified layers 307b. The epitaxial S/D features 146 may be formed using the same process as discussed above with respect to FIGS. 15A-15C. Since the semiconductor (i.e., epitaxial S/D features 146) may not grow, or does not grow well on the dielectric material (e.g., second modified layers 307b), a bottom portion of the epitaxial S/D feature 146 may separate from the second modified layer 307b by an air gap 415. Likewise, the semiconductor device structure 400 may undergo further processes, such as the processes described above with respect to FIGS. 15A-15C and 17A-17C to 21A-21C.

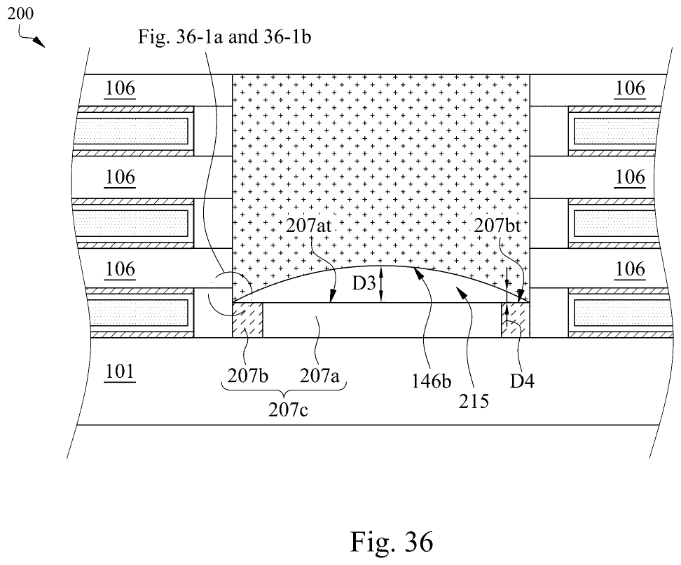

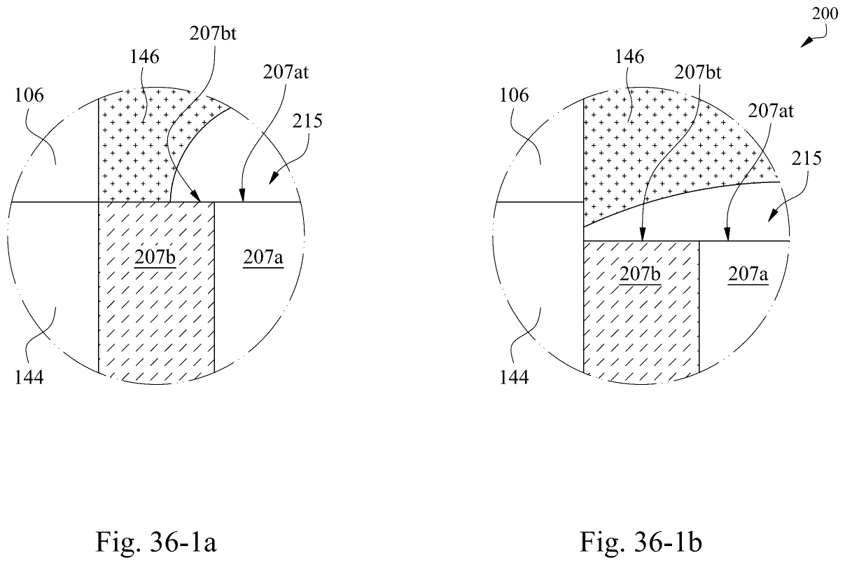

FIGS. 36-40 illustrate an enlarged view of a portion of the semiconductor device structure 200 shown in FIG. 28, in accordance with some embodiments. While not shown, these embodiments are equally applicable to the semiconductor device structures 300 and 400 of FIGS. 31 and 35, respectively. In FIG. 36, the epitaxial S/D feature 146 is disposed above the first and second modified layers 207a, 207b. In some embodiments, the first modified layer 207a is surrounded by the second modified layer 207b. The top surfaces of the first and second modified layers 207a, 207b are substantially co-planar. The bottom surfaces of the first and second modified layers 207a, 207b are in contact with the top surface of the substrate 101. The epitaxial S/D feature 146 is disposed between and in contact with two neighboring first semiconductor layers 106 and inner spacers 144. The bottom surface 146b of the epitaxial S/D feature 146 may have a curved surface which separates the epitaxial S/D feature 146 from the first and second modified layers 207a, 207b by the air gap 215. The air gap 215 is confined by the epitaxial S/D feature 146, the top surface 207at of the first modified layer 207a, the top surface 207bt of the second dielectric layer 207b.

In some embodiments, the epitaxial S/D feature 146 does not contact the first and second modified layers 207a, 207b. In some embodiments, an edge portion of the epitaxial S/D feature 146 may be in slight contact with the second modified layer 207b, as shown in FIG. 36-1a. In some embodiments, an edge portion of the epitaxial S/D feature 146 is in contact with the second modified layer 207b but not the first modified layer 207a. In some embodiments, an edge portion of the epitaxial S/D feature 146 is in contact with the inner spacer 144, without touching the first and second modified layers 207a, 207b, as shown in FIG. 36-1b. In this embodiment, the air gap 215 is confined by the epitaxial S/D feature 146, the top surface 207at of the first modified layer 207a, the top surface 207bt of the second modified layer 207b, and the sidewall surface of the inner spacer 144.

In some embodiments, the top surface 207at of the first modified layer 207a is separated from the bottom surface 146b of the epitaxial S/D feature 146 by a vertical distance D3, and the top surface 207bt of the second modified layer 207b is separated from the bottom surface 146b of the epitaxial S/D feature 146 by a vertical distance D4, which is less than the vertical distance D3.

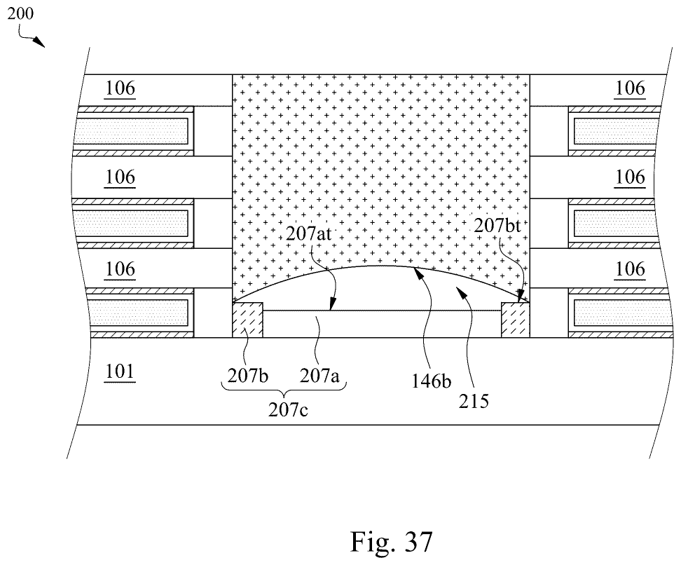

FIG. 37 illustrates an embodiment similar to the embodiment of FIG. 36 except that the top surface 207at of the first modified layer 207a and the top surface 207bt of the second modified layer 207b are at different heights. For example, the top surface 207at of the first modified layer 207a may be at an elevation lower than the top surface 207bt of the second modified layer 207b. In some embodiments, the top surface 207at of the first modified layer 207a may be at an elevation higher than the top surface 207bt of the second modified layer 207b.

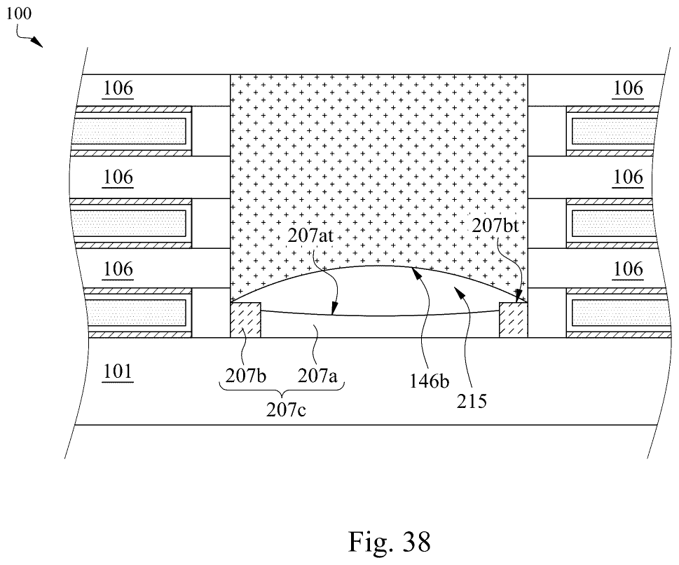

FIG. 38 illustrates an embodiment similar to the embodiment of FIG. 37 except that the top surface 207at of the first modified layer 207a has a curved surface (e.g., concave profile), which may be formed as a result of an isotropic etchant used by the etch process 175-2. In this embodiment, the highest point of the first modified layer 207a, such as the peripheral edge of the top surface 207at of the first modified layer 207a, is lower than the top surface 207bt of the second modified layer 207b.

FIG. 39 illustrates an embodiment similar to the embodiment of FIG. 38 except that the substrate 101 between neighboring replacement gate structures 190 has a curved (e.g., convex) top surface 101t. In such cases, the first modified layer 207a deposited thereon may have a curved bottom surface that follows the curved profile of the top surface 101t of the substrate 101. In some embodiments, the top surface 207bt of the second modified layer 207b may also have a curved profile (e.g., convex). In such cases, the top surface 207at of the first modified layer 207a may have a first curvature, and the top surface 207bt of the second modified layer 207b may have a second curvature that is smaller than the first curvature. In some embodiments, the top surfaces 207at, 207bt of the first and second modified layers 207a, 207b have a curved profile that is opposite to the top surface 101t of the substrate 101.

FIG. 40 illustrates an embodiment similar to the embodiment of FIG. 39 except that the first and second modified layers 207a, 207b have a profile that follows the top surface 101t of the substrate 101. In the embodiments where the top surface 101t of the substate 101 has a curved (e.g., convex) profile, the first modified layer 207a is deposited to have a curved (e.g., convex) profile. In some embodiments, the highest point of the second modified layer 207b may be at an elevation lower than the top surface 207at of the first modified layer 207a. In some embodiments, the highest point of the second modified layer 207b may be at an elevation higher than the top surface 207at of the first modified layer 207a.

While not shown in the embodiments of FIGS. 37-40, it is contemplated that in some embodiments the top surface 207at of the first modified layer 207a is separated from the bottom surface 146b of the epitaxial S/D feature 146 by a first vertical distance, and the top surface 207bt of the second modified layer 207b is separated from the bottom surface 146b of the epitaxial S/D feature 146 by a second vertical distance that is less than the first vertical distance.

Various embodiments of the present disclosure relate to new approaches of forming a dielectric layer structure over exposed surfaces of sacrificial gate structure and stack of semiconductor layers prior to formation of source/drain features. Portions of the dielectric layer structure are etched and remain between a bottom of the source/drain feature and a top surface of the substrate for source/drain epitaxy leakage reduction and parasitic capacitance reduction. In various embodiments, an inner dielectric layer of the dielectric layer structure is deposited to create an etch rate difference between inner spacers and sidewall surface of an outer dielectric layer of the dielectric layer structure in order to reduce inner spacer dishing during downstream etching processes. As a result, the integrity of the inner spacers is preserved, which prevents air gap from forming between the inner spacer and the source/drain feature and degrading device performance.

An embodiment is a semiconductor device structure. The semiconductor device structure includes a source/drain (S/D) feature disposed over a substrate and between two adjacent semiconductor layers, an inner spacer disposed between and in contact with one of the semiconductor layers and the substrate, and a dielectric layer structure disposed between the S/D feature and the substrate, the dielectric layer structure comprising a first dielectric layer in contact with the inner spacer and the substrate, and a second dielectric layer nested within the first dielectric layer, wherein a bottom surface and sidewall surfaces of the second dielectric layer are in contact with the first dielectric layer, and a bottom surface of the S/D feature, the first dielectric layer, the second dielectric layer, and the inner spacer define an air gap therebetween.

Another embodiment is a method for forming a semiconductor device structure. The method includes forming a first fin structure and a second fin structure from a substrate, each fin structure comprising a plurality of first semiconductor layers and a plurality of second semiconductor layers alternately stacked, depositing a sacrificial gate structure over a portion of the first and second fin structures; removing portions of the first and second fin structures not covered by the sacrificial gate structure to form a recess, forming an inner spacer at an edge of each second semiconductor layer, depositing a first dielectric layer on exposed surfaces of the sacrificial gate structure, the inner spacers, the first semiconductor layers, and the substrate, depositing a second dielectric layer on the first dielectric layer, removing the first and second dielectric layers from sidewall surfaces of the sacrificial gate structure, the first semiconductor layers, and the inner spacers, while retaining the first and second dielectric layers over the substrate to form a dielectric layer structure, forming a source/drain (S/D) feature over the dielectric layer structure, wherein a bottom surface of the S/D feature, the dielectric layer structure, and the inner spacer define an air gap therebetween, removing the sacrificial gate structure and the second semiconductor layers to expose portions of the first semiconductor layers, and forming a gate electrode layer surrounding the exposed portions of the first semiconductor layers.

A further embodiment is a method for forming a semiconductor device structure. The method includes providing a substrate with a first fin structure and a second fin structure, each comprising a stack of alternating first and second semiconductor layers, forming a sacrificial gate structure over a portion of the first and second fin structures; etching portions of the first and second fin structures not covered by the sacrificial gate structure to form a recess, forming inner spacers at edges of the second semiconductor layers, depositing a base layer on a top surface of the substrate within the recess using a bottom-up epitaxial growth process, treating the base layer with a plasma treatment process to convert the base layer into a supporting layer with a curved top surface, forming a source/drain (S/D) feature over the supporting layer, wherein an air gap is maintained between the S/D feature, the supporting layer, the inner spacers, and the substrate; removing the sacrificial gate structure and the second semiconductor layers to expose portions of the first semiconductor layers, and forming a replacement gate structure surrounding the exposed portions of the first semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a source/drain (S/D) feature disposed over a substrate and between two adjacent semiconductor layers;
an inner spacer disposed between and in contact with one of the semiconductor layers and the substrate; and
a dielectric layer structure disposed between the S/D feature and the substrate, the dielectric layer structure comprising:
a first dielectric layer in contact with the inner spacer and the substrate; and
a second dielectric layer nested within the first dielectric layer, wherein a bottom surface and sidewall surfaces of the second dielectric layer are in contact with the first dielectric layer, and a bottom surface of the S/D feature, the first dielectric layer, the second dielectric layer, and the inner spacer define an air gap therebetween.

2. The semiconductor device structure of claim 1, wherein the first dielectric layer comprises an oxide-based material, and the second dielectric layer comprises a nitride-based material.

3. The semiconductor device structure of claim 1, wherein a top surface of the first dielectric layer is at an elevation different from a top surface of the second dielectric layer.

4. The semiconductor device structure of claim 1, wherein the top surface of the second dielectric layer has a concave profile.

5. The semiconductor device structure of claim 1, wherein the substrate has a convex top surface in contact with the dielectric layer structure.

6. The semiconductor device structure of claim 1, wherein the bottom surface of the S/D feature has a concave curvature.

7. The semiconductor device structure of claim 1, wherein the first dielectric layer has a thickness in a range of about 4 nm to about 6 nm.

8. The semiconductor device structure of claim 1, wherein the inner spacer comprises a material selected from the group consisting of SiON, SiCN, SiOC, SiOCN, and SiN.

9. A method for forming a semiconductor device structure, comprising:
forming a first fin structure and a second fin structure from a substrate, each fin structure comprising a plurality of first semiconductor layers and a plurality of second semiconductor layers alternately stacked;
depositing a sacrificial gate structure over a portion of the first and second fin structures; removing portions of the first and second fin structures not covered by the sacrificial gate structure to form a recess;
forming an inner spacer at an edge of each second semiconductor layer;
depositing a first dielectric layer on exposed surfaces of the sacrificial gate structure, the inner spacers, the first semiconductor layers, and the substrate;
depositing a second dielectric layer on the first dielectric layer; removing the first and second dielectric layers from sidewall surfaces of the sacrificial gate structure, the first semiconductor layers, and the inner spacers, while retaining the first and second dielectric layers over the substrate to form a dielectric layer structure;
forming a source/drain (S/D) feature over the dielectric layer structure, wherein a bottom surface of the S/D feature, the dielectric layer structure, and the inner spacer define an air gap therebetween;
removing the sacrificial gate structure and the second semiconductor layers to expose portions of the first semiconductor layers; and
forming a gate electrode layer surrounding the exposed portions of the first semiconductor layers.

10. The method of claim 9, wherein depositing the first dielectric layer comprises using an atomic layer deposition (ALD) process with an oxide-based material.

11. The method of claim 9, wherein depositing the second dielectric layer comprises using a plasma-based deposition process with a nitride-based material.

12. The method of claim 9, wherein removing the first and second dielectric layers from the sidewall surfaces comprises performing a wet etch process using a solution selected from the group consisting of ammonium hydroxide, hydrofluoric acid, and tetramethylammonium hydroxide.

13. The method of claim 9, further comprising:
performing a pre-clean process using a diluted hydrofluoric acid solution to enhance an etch profile of the dielectric layer structure over the substrate.

14. The method of claim 9, wherein the air gap is confined by the bottom surface of the S/D feature, top surfaces of the first and second dielectric layers, and a sidewall of the inner spacer.

15. A method for forming a semiconductor device structure, comprising:
providing a substrate with a first fin structure and a second fin structure, each comprising a stack of alternating first and second semiconductor layers;
forming a sacrificial gate structure over a portion of the first and second fin structures; etching portions of the first and second fin structures not covered by the sacrificial gate structure to form a recess;
forming inner spacers at edges of the second semiconductor layers;
depositing a base layer on a top surface of the substrate within the recess using a bottom-up epitaxial growth process;
treating the base layer with a plasma treatment process to convert the base layer into a supporting layer with a curved top surface;
forming a source/drain (S/D) feature over the supporting layer, wherein an air gap is maintained between the S/D feature, the supporting layer, the inner spacers, and the substrate; removing the sacrificial gate structure and the second semiconductor layers to expose portions of the first semiconductor layers; and
forming a replacement gate structure surrounding the exposed portions of the first semiconductor layers.

16. The method of claim 15, wherein the plasma treatment process comprises exposing the base layer to nitrogen radicals generated from a nitrogen-containing gas at a pressure of about 0.5 Torr to about 8 Torr.

17. The method of claim 15, further comprising:
trimming the base layer using a wet etch process prior to the plasma treatment process to reduce a thickness of the base layer to a range of about 4 nm to about 6 nm.

18. The method of claim 15, wherein the supporting layer comprises silicon nitride formed by a nitridation process.

19. The method of claim 15, further comprising:
forming a liner on the top surface of the substrate and sidewalls of the first semiconductor layers before depositing the base layer, wherein the liner comprises boron-doped silicon.

20. The method of claim 15, wherein the curved top surface of the supporting layer has a highest point at an elevation between a top surface and a bottom surface of a bottommost first semiconductor layer.
